(19) United States
(12) Patent Application Publication
(10) Pub. No.: US 2024/0178242 A1
(43) Pub. Date: May 30, 2024

(54) IMAGE SENSOR DEVICE AND OPERATION METHOD THEREOF

(71) Applicant: Samsung Electronics Co., Ltd., Suwon-si (KR)

(72) Inventors: Suyong KIM, Suwon-si (KR); Jaeyoung BAE, Suwon-si (KR); Yunhwan JUNG, Suwon-si (KR)

(73) Assignee: Samsung Electronics Co., Ltd., Suwon-si (KR)

(21) Appl. No.: 18/359,004

(22) Filed: Jul. 26, 2023

(30) Foreign Application Priority Data
Nov. 25, 2022 (KR) 10-2022-0160332

(51) Int. Cl. H01L 27/146; H04N 25/76; H04N 25/77; H04N 25/78

(52) U.S. Cl. CPC H01L 27/14612; H04N 25/77; H04N 25/7795; H04N 25/78

(57) ABSTRACT

An image sensor device includes a first pixel that is located at a first row and a first column and comprising a first select transistor and is configured to output a first pixel signal through a first column line, and a second pixel that is located at a second row different from the first row and the first column and comprising a second select transistor and is configured to output a second pixel signal through a second column line. During a first time period, the first select transistor is turned on and the first pixel signal is output, and during a second time period, the second select transistor is turned on, and a first voltage is applied to the second column line through the second select transistor, the second time period including the first time period.

### CROSS-REFERENCE TO RELATED APPLICATIONS

This application claims priority to Korean Patent Application No. 10-2022-0160332 filed on Nov. 25, 2022, in the Korean Intellectual Property Office, the disclosures of which are incorporated by reference herein in their entireties.

### BACKGROUND

Example embodiments of the present inventive concepts described herein relate to image sensors, and more particularly, relate to image sensor devices and operation methods thereof.

An image sensor converts a light (e.g., incident light) received from the outside (e.g., an exterior of the image sensor) into an electrical signal. The image sensor may be classified as a complementary metal-oxide-semiconductor (CMOS) image sensor or a charge coupled device (CCD) image sensor.

As the resolution of image data increases, nowadays, the number of pixels of the image sensor is increasing, and a time taken to read out data from the image sensor is decreasing. For example, a time period where the image sensor reads out data to be output through data lines is decreasing. As such, there are developed various techniques for securing a time taken to stabilize a data line voltage. In particular, nowadays, a high frame rate (HFR) technology for providing a pixel value at high speed is required in the CMOS image sensor field. To implement the HFR operation, it is important to decrease a settling time of a column data line in a correlated double sampling (CDS) and analog-to-digital conversion (ADC) operation.

### SUMMARY

Some example embodiments of the present inventive concepts provide an image sensor device with improved performance and/or an operation method thereof.

According to some example embodiments, an image sensor device includes a first pixel that is located at a first row and a first column and comprising a first select transistor and is configured to output a first pixel signal through a first column line, and a second pixel that is located at a second row different from the first row and the first column and comprising a second select transistor and is configured to output a second pixel signal through a second column line. During a first time period, the first select transistor is turned on and the first pixel signal is output, and during a second time period, the second select transistor is turned on, and first voltage is applied to the second column line through the second select transistor, the second period including the first period.

According to some example embodiments, an image sensor device includes a first pixel that is located at a first row and a first column and comprising a first select transistor and is configured to output a first pixel signal through a first column line, a second pixel that is located at a second row different from the first row and the first column and comprising a second select transistor and is configured to output a second pixel signal through a second column line, and a third pixel that is located at a third row different from the first row and the second row and the first column and comprising a third select transistor and is configured to output a third pixel signal through the first column line. During a first time period and a second time period, the first select transistor is turned on and the first pixel signal is output, during a third time period, the second select transistor is turned on, and a first voltage is applied to the second column line through the second select transistor, the second time period including the first time period and the second time period, and during a fourth time period, the first select transistor is turned off, the third select transistor is turned on, and a second voltage is applied to the first column line through the third select transistor, the fourth time period between the first time period and the second time period.

According to some example embodiments, an operation method of an image sensor device which includes a first pixel located at a first row and a first column and including a first select transistor, a second pixel located at a second row and the first column and including a second select transistor, the second row different from the first row, a first column line connected to the first pixel, and a second column line connected to the second pixel may include performing a first readout operation based on turning on the first select transistor and starting an operation of applying a first voltage to the second column line based on turning on the second select transistor, terminating the first readout operation based on turning off the first select transistor and performing a shutter operation, terminating the shutter operation based on turning on the first select transistor and performing a second readout operation, and terminating the second readout operation based on turning off the first select transistor and terminating an operation of applying the first voltage to the second column line based on turning off the second select transistor, wherein an address of the second row may be based on an address of the first row.

### BRIEF DESCRIPTION OF THE DRAWINGS

The above and other objects and features of the present inventive concepts will become apparent by describing in detail some example embodiments thereof with reference to the accompanying drawings.

FIG. 1 is a block diagram illustrating an image sensor device according to some example embodiments of the present inventive concepts.

FIG. 2 is a diagram illustrating an example of a stack-type structure of an image sensor device of FIG. 1 according to some example embodiments of the present inventive concepts.

FIG. 3 is a block diagram illustrating a partial configuration of an image sensor device of FIG. 1 in detail according to some example embodiments of the present inventive concepts.

FIG. 4 is a circuit diagram illustrating an active load circuit of FIG. 1 according to some example embodiments of the present inventive concepts.

FIG. 5A is a circuit diagram illustrating an example of one of pixels in a pixel array of FIG. 1 according to some example embodiments of the present inventive concepts.

FIG. 5B is a circuit diagram illustrating another example of one of pixels in a pixel array of FIG. 1 according to some example embodiments of the present inventive concepts.

FIG. 6A is a diagram for describing a pixel output level control operation according to a column line change, according to some example embodiments of the present inventive concepts.

FIG. 6B is a timing diagram for describing a pixel output level control operation according to a column line change of FIG. 6A according to some example embodiments of the present inventive concepts.

FIG. 7A is a diagram illustrating an example of a configuration of a row driver of FIG. 1 according to some example embodiments of the present inventive concepts.

FIG. 7B is a logic circuit diagram illustrating an example of a partial configuration of a selection logic circuit of FIG. 7A in detail according to some example embodiments of the present inventive concepts.

FIG. 8A is a circuit diagram illustrating a line disconnection circuit of FIG. 1 according to some example embodiments of the present inventive concepts.

FIG. 8B is a diagram for describing an issue of a line disconnection circuit of FIG. 8A in detail according to some example embodiments of the present inventive concepts.

FIG. 9A is a diagram illustrating a pixel output level control operation of image sensor including a line disconnection circuit according to some example embodiments of the present inventive concepts.

FIG. 9B is a timing diagram for describing a pixel output level control operation of FIG. 9A according to some example embodiments of the present inventive concepts.

FIG. 10 is a diagram illustrating an example of a configuration of a row driver of FIG. 1 according to some example embodiments of the present inventive concepts.

FIG. 11 is a flowchart illustrating an example of an operation method of an image sensor device according to some example embodiments of the present inventive concepts.

### DETAILED DESCRIPTION

Below, some example embodiments of the present inventive concepts will be described in detail and clearly to such an extent that one skilled in the art easily carries out the present inventive concepts.

In the detailed description, components described with reference to the terms “unit”, “module”, “block”, “˜er or ˜or”, etc. and function blocks illustrated in drawings will be implemented with software, hardware, or any combination thereof. For example, the software may be a machine code, firmware, an embedded code, and/or application software. For example, the hardware may include an electrical circuit, an electronic circuit, a processor, a computer, an integrated circuit, integrated circuit cores, a pressure sensor, an inertial sensor, a microelectromechanical system (MEMS), a passive element, or any combination thereof.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

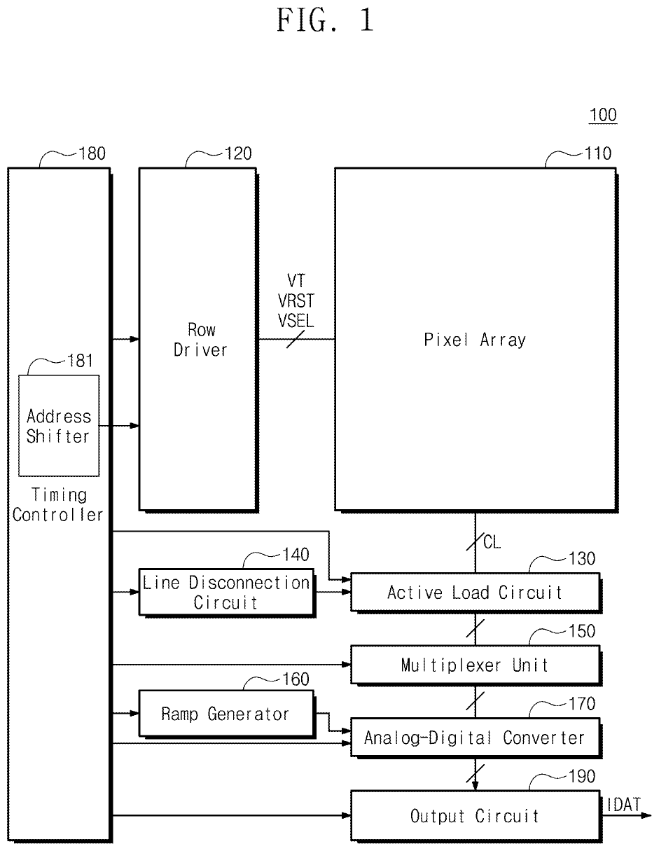

FIG. 1 is a block diagram illustrating an image sensor device according to some example embodiments of the present inventive concepts. Referring to FIG. 1, an image sensor device 100 may include a pixel array 110, a row driver 120, an active load circuit 130, a line disconnection circuit 140, a multiplexer unit 150, a ramp generator 160, an analog-digital converter 170, a timing controller 180, and an output circuit 190.

The pixel array 110 may include a plurality of pixels arranged in a row direction and a column direction. Each of the plurality of pixels may generate a pixel signal under control of the row driver 120. For example, the pixel signals generated by the plurality of pixels may be output through column lines CL.

The row driver 120 may select and drive a row of the pixel array 110. The row driver 120 may be connected to the pixel array 110 through a plurality of signal lines. The row driver 120 may decode addresses generated by the timing controller 180 and may generate control signals for selecting and driving a row of the pixel array 110. The row driver 120 may provide the control signals to the plurality of pixels through a plurality of signal lines. For example, the control signals may include a transfer signal VT, a selection signal VSEL, a reset signal VRST, etc. The row driver 120 may include latch circuits for storing the addresses and logic circuits for providing the control signals to the pixel array 110.

The active load circuit 130 may be connected to the pixel array 110 through the column lines CL. The active load circuit 130 may individually enable or disable the column lines CL connected to the pixels of the pixel array 110 under control of the timing controller 180. The active load circuit 130 may transfer the pixel signals output through the column lines CL to the multiplexer unit 150.

To control pixel output levels of the column lines CL of the pixel array 110, the line disconnection circuit 140 may adjust the voltage levels of the column lines CL to a desired voltage level under control of the timing controller 180.

Meanwhile, the image sensor device 100 of the present inventive concepts may not include the line disconnection circuit 140. In some example embodiments, the image sensor device 100 may control the control signals to be applied to each pixel for the purpose of adjusting voltage levels of the column lines CL of the pixel array 110. An operation of the line disconnection circuit 140 will be described in detail with reference to the following drawings.

The multiplexer unit 150 may receive the pixel signals output from the plurality of column lines CL. The multiplexer unit 150 may select some of the plurality of column lines CL under control of the timing controller 180. The multiplexer unit 150 may output the pixel signals transferred through the selected column lines to the analog-digital converter 170.

The ramp generator 160 may generate a ramp signal under control of the timing controller 180. For example, the ramp generator 160 may operate in response to a control signal such as a ramp enable signal. When the ramp enable signal is activated, the ramp generator 160 may generate the ramp signal depending on preset values (e.g., a start level, an end level, and a slope). In other words, the ramp signal may be a signal that increases or decreases along a preset slope during a specific time. The ramp signal may be provided to the analog-digital converter 170.

The analog-digital converter 170 may receive the pixel signals from the plurality of pixels of the pixel array 110 through the column lines CL, the active load circuit 130, and the multiplexer unit 150 and may receive the ramp signal from the ramp generator 160. The analog-digital converter 170 may operate based on a correlated double sampling (CDS) technique for obtaining a reset signal and an image signal from the received pixel signal and extracting a difference between the reset signal and the image signal as an effective signal component. The timing controller 180 may control the row driver 120, the active load circuit 130, the line disconnection circuit 140, the multiplexer unit 150, the ramp generator 160, the analog-digital converter 170, and the output circuit 190.

In particular, the timing controller 180 of the present inventive concepts may include an address shifter 181 for performing (e.g., configured to perform) an operation of controlling a pixel output level based on a column line change by the pixel array 110. In detail, the address shifter 181 may determine an address of a pixel adjacent to a pixel under the readout operation and may provide the determined address to the row driver 120.

The output circuit 190 may receive digital signals from the analog-digital converter 170. The output circuit 190 may combine the received digital signals and may output final image data IDAT.

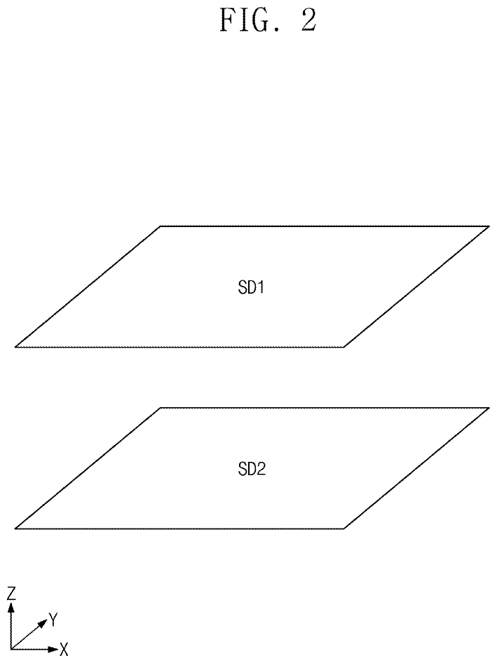

FIG. 2 is a diagram illustrating an example of a stack-type structure of an image sensor device of FIG. 1 according to some example embodiments of the present inventive concepts. Referring to FIG. 2, the image sensor device 100 may have a structure in which at least two semiconductor substrates that include a first semiconductor substrate SD1 and a second semiconductor substrate SD2 under the first semiconductor substrate SD1 are stacked in a vertical direction “Z”. A row direction “X” and a column direction “Y” may be directions that are at right angles and are parallel to a surface of a semiconductor substrate (e.g., at least one of the first semiconductor substrate SD1 or the second semiconductor substrate SD2).

Pads may be formed on the lower surface of the first semiconductor substrate SD1 and the upper surface of the second semiconductor substrate SD2 such that locations of the pads coincide with each other (e.g., each pad on the lower surface of the first semiconductor substrate SD1 may at least partially overlap in the vertical direction “Z” with a separate, respective pad that is on the upper surface of the second semiconductor substrate SD2), and the first semiconductor substrate SD1 and the second semiconductor substrate SD2 may be electrically connected through the pads.

For example, the pixel array 110 of FIG. 1 may be formed on the first semiconductor substrate SD1, and the remaining components other than the pixel array 110 of FIG. 1 may be formed on the second semiconductor substrate SD2. For example, the first semiconductor substrate SD1 and the second semiconductor substrate SD2 may be electrically connected through logic circuits of the row driver 120.

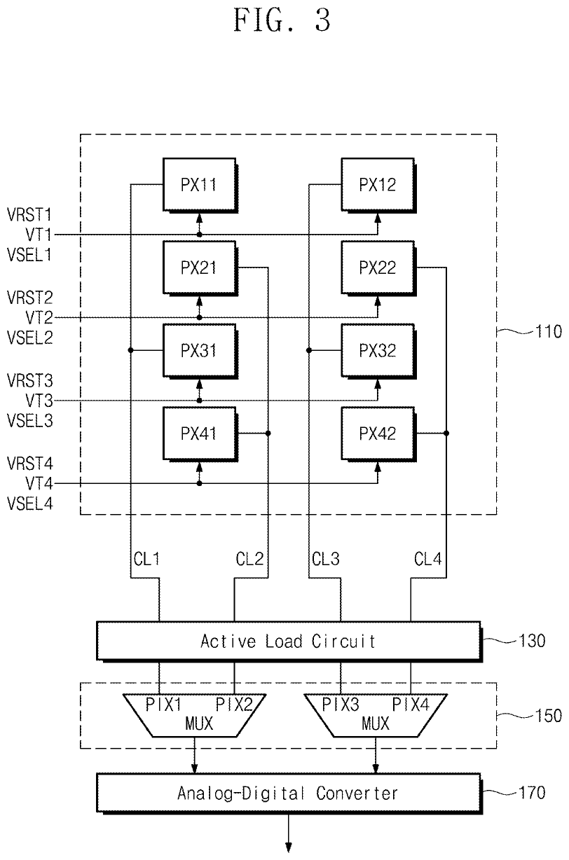

FIG. 3 is a block diagram illustrating a partial configuration of an image sensor device of FIG. 1 in detail according to some example embodiments of the present inventive concepts. For brevity of drawing and for convenience of description, a partial configuration of the image sensor device 100 is illustrated, but the present inventive concepts are not limited thereto. Also, in some example embodiments, including the example embodiments shown in FIG. 3, the pixel array 110 may include a plurality of pixels PX11 to PX42 that are arranged along first to fourth rows and first to second columns (i.e., to form a 4×2 matrix), but the present inventive concepts are not limited thereto. For example, the plurality of pixels PX11 to PX42 of the pixel array 110 may be expanded in the row direction and the column direction, and thus, pixels may be further included in the pixel array 110.

In some example embodiments, the pixel array 110 may include various types of color filter arrays. For example, the pixel array 110 may include a color filter array configured to allow each pixel to receive a light signal corresponding to a given color.

In some example embodiments, the color filter array may include at least one of various color filter array patterns such as a Bayer pattern, an RGBE pattern, a CYYM pattern, a CYGM pattern, a BGBW Bayer pattern, a BGBW pattern, and a tetra pattern.

Referring to FIGS. 1 and 3, the image sensor device 100 may include the pixel array 110, the active load circuit 130, the multiplexer unit 150, and the analog-digital converter 170. The pixel array 110 of FIG. 3 may include the pixels PX11 to PX42 of four rows and two columns.

In some example embodiments, the pixels PX11 to PX42 may be configured to receive the control signals from the row driver 120. The control signals may be input to pixels located at a relevant row. For example, the image sensor device 100 may be configured to cause the control signals to be input (e.g., transmitted) to pixels located at a relevant row. For example, the pixels PX11 and PX12 located at the first row may receive the first control signal. For example, the first control signal may include a first reset signal VRST1, a first transfer signal VT1, and a first selection signal VSEL1. For example, the pixels PX41 and PX42 located at the fourth row may receive the fourth control signal. For example, the fourth control signal may include a fourth reset signal VRST4, a fourth transfer signal VT4, and a fourth selection signal VSEL4.

In some example embodiments, pixels located at odd-numbered rows may be connected to odd-numbered column lines, and pixels located at even-numbered rows may be connected to even-numbered column lines. For example, the pixels PX11 and PX31 located at the odd-numbered rows and the first column from among the plurality of pixels of the pixel array 110 may be connected to the first column line CL1; the pixels PX21 and PX41 located at the even-numbered rows and the first column from among the plurality of pixels of the pixel array 110 may be connected to the second column line CL2; the pixels PX12 and PX32 located at the odd-numbered rows and the second column from among the plurality of pixels of the pixel array 110 may be connected to the third column line CL3; and, the pixels PX22 and PX42 located at the even-numbered rows and the second column from among the plurality of pixels of the pixel array 110 may be connected to the fourth column line CL4.

In some example embodiments, the plurality of pixels PX11 to PX42 may generate (e.g., may be configured to generate) first to fourth pixel signals PIX1 to PIX4. Pixel signals generated by the plurality of pixels PX11 to PX42 may be output (e.g., transmitted) through column lines connected to the plurality of pixels PX11 to PX42. For example, each of the pixels PX11 and PX31 connected to the first column line CL1 from among the plurality of pixels PX11 to PX42 may generate the first pixel signal PIX1, and the first pixel signal PIX1 may be output through the first column line CL1. Each of the pixels PX22 and PX42 connected to the fourth column line CL4 may generate the fourth pixel signal PIX4, and the fourth pixel signal PIX4 may be output through the fourth column line CL4.

In some example embodiments, the voltage of each of the first to fourth pixel signals PIX1 to PIX4 may be a reset voltage generated through the reset operation of the corresponding pixel or may be a data voltage generated through the shutter operation.

The multiplexer unit 150 may be connected to the first to fourth column lines CL1 to CL4 through the active load circuit 130. The multiplexer unit 150 may receive the first to fourth pixel signals PIX1 to PIX4 through the first to fourth column lines CL1 to CL4 and the active load circuit 130.

In some example embodiments, the multiplexer unit 150 may include a plurality of multiplexers MUX. Under control of the timing controller 180, the multiplexer unit 150 may select the pixel signals PIX1 and PIX3 transferred through the odd-numbered column lines CL1 and CL3 or the pixel signals PIX2 and PIX4 transferred through the even-numbered column lines CL2 and CL4, so as to be output to the analog-digital converter 170. For example, the image sensor device 100 may be configured to, based on the timing controller 180 controlling the multiplexer unit 150, cause the multiplexer unit 150 to select the pixel signals PIX1 and PIX3 transferred through the odd-numbered column lines CL1 and CL3 or the pixel signals PIX2 and PIX4 transferred through the even-numbered column lines CL2 and CL4, so as to be output to the analog-digital converter 170.

For example, in an arbitrary time period, when the readout operation is performed on the pixels PX31 and PX32 at the third row, the multiplexers MUX may output the odd-numbered pixel signals PIX1 and PIX3 to the analog-digital converter 170. In this case, the analog-digital converter 170 may fail to receive the even-numbered pixel signals PIX2 and PIX4. After the arbitrary time period, when the readout operation is performed on the pixels PX41 and PX42 at the fourth row, the multiplexers MUX may output the even-numbered pixel signals PIX2 and PIX4 to the analog-digital converter 170. In this case, the analog-digital converter 170 may fail to receive the odd-numbered pixel signals PIX1 and PIX3.

In some example embodiments, unlike some example embodiments, including the example embodiments illustrated in FIG. 3, the pixel array 110 may be implemented such that locations of column lines connected to pixels are changed every plural rows. For example, column lines connected to pixels every two rows may be switched from the odd-numbered column lines CL1 and CL3 to the even-numbered column lines CL2 and CL4 or from the even-numbered column lines CL2 and CL4 to the odd-numbered column lines CL1 and CL3.

In some example embodiments, for example, the pixels PX11 and PX21 located at the first and second rows and the first column may be connected to the first column line CL1; the pixels PX12 and PX22 located at the first and second rows and the second column may be connected to the third column line CL3; the pixels PX31 and PX41 located at the third and fourth rows and the first column may be connected to the second column line CL2; and, the pixels PX32 and PX42 located at the third and fourth rows and the second column may be connected to the fourth column line CL4. That is, column lines connected to pixels every two rows may be switched from the odd-numbered column lines CL1 and CL3 to the even-numbered column lines CL2 and CL4 or from the even-numbered column lines CL2 and CL4 to the odd-numbered column lines CL1 and CL3.

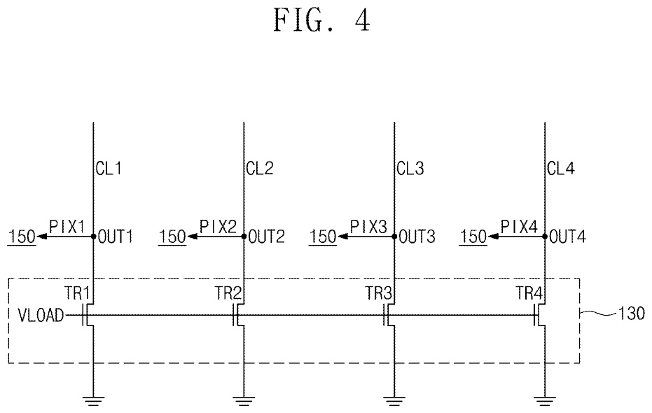

FIG. 4 is a circuit diagram illustrating an active load circuit of FIG. 1 according to some example embodiments of the present inventive concepts. The active load circuit 130 may include transistors TR1 to TR4 that are respectively connected with the column lines CL1 to CL4 of the pixel array 110. The transistors TR1 to TR4 may be turned on in response to a load voltage VLOAD and may operate as a current source. For example, the load voltage VLOAD may be provided under control of the timing controller 180 of FIG. 1.

In detail, the transistors TR1 to TR4 may be turned on by the load voltage VLOAD of the high level and so as to operate as a current source, and the pixel signals PIX1 to PIX4 output from pixels connected to the column lines CL1 to CL4 may be provided to the multiplexer unit 150. In some example embodiments, voltage levels of the output pixel signals PIX1 to PIX4 may be identical to voltage levels of output voltages OUT1 to OUT4.

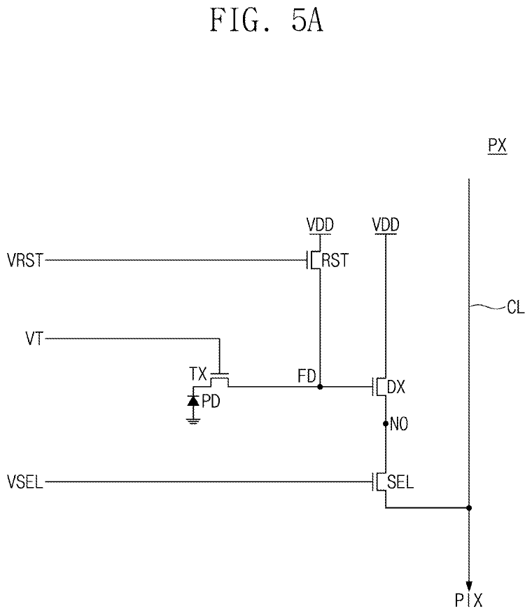

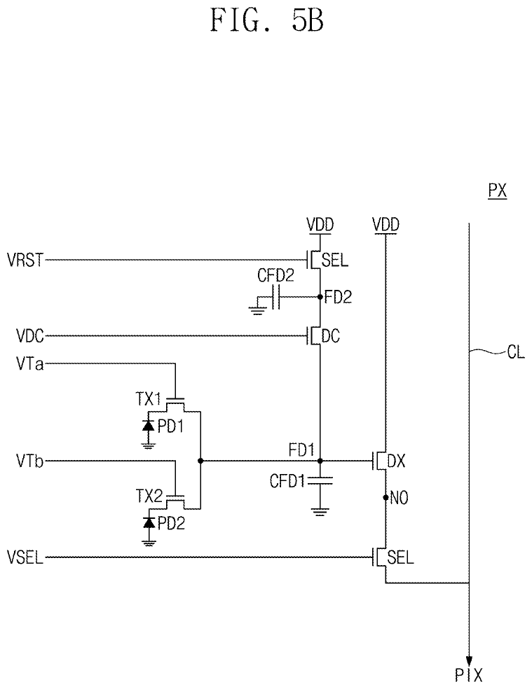

FIG. 5A is a circuit diagram illustrating an example of one pixel PX of a plurality of pixels in a pixel array 110 of FIG. 1 according to some example embodiments of the present inventive concepts. Referring to FIGS. 1 and 5A, the pixel PX may generate (e.g., may be configured to generate) the pixel signal PIX in response to the reset signal VRST, the transfer signal VT, and the selection signal VSEL from the row driver 120 and may output (e.g., transmit) the pixel signal PIX through the column line CL. In some example embodiments, “outputting” a pixel signal in response to a control signal may include generating and transmitting the pixel signal.

For example, the pixel PX may include a transfer transistor TX, a photo diode PD, a reset transistor RST, a drive transistor DX, and a select transistor SEL.

FIG. 5A shows a structure in which the pixel PX includes one photo diode PD and one transfer transistor TX, but the present inventive concepts are not limited thereto. For example, the pixels of the pixel array 110 may be implemented with (e.g., may include) various different structures.

The photo diode PD may be configured to integrate (or accumulate) charges in response to a light signal received from the outside. The transfer transistor TX may be connected between the photo diode PD and a floating diffusion node FD. The transfer transistor TX may operate (e.g., may be configured to operate) in response to the transfer signal VT from the row driver 120. For example, the transfer transistor TX may be turned on (e.g., may be configured to be turned on) in response to the transfer signal VT of the logic high level. While the transfer transistor TX is turned on in response to the transfer signal VT of the logic high level, the charges may be transferred from the photo diode PD to the floating diffusion node FD. As such, the voltage of the floating diffusion node FD may decrease.

The reset transistor RST may be connected between a power supply voltage VDD and the floating diffusion node FD. The reset transistor RST may operate (e.g., may be configured to operate) in response to the reset signal VRST from the row driver 120. For example, the reset transistor RST may be turned on (e.g., may be configured to turn on) in response to the reset signal VRST of the logic high level. While the reset transistor RST is turned on in response to the reset signal VRST of the logic high level, the floating diffusion node FD may be reset. As such, the floating diffusion node FD may be charged with a reset voltage. The reset voltage may be determined based on (e.g., may be based on) the voltage level of the reset signal VRST. As described herein, a “voltage level” of a signal may be a magnitude of the voltage of the signal. In some example embodiments, the image sensor device 100 may control a magnitude of the reset voltage by adjusting the voltage level of the reset signal VRST of the logic high level.

The drive transistor DX may be connected between the power supply voltage VDD and a 0-th node NO. The drive transistor DX may operate (e.g., may be configured to operate) in response to the voltage of the floating diffusion node FD. For example, the gate terminal of the drive transistor DX may be connected to the floating diffusion node FD. In some example embodiments, the drive transistor DX may be configured to transfer the pixel signal PIX corresponding to the variation in the voltage of the floating diffusion node FD to the select transistor SEL through the 0-th node NO. That is, the drive transistor DX may operate (e.g., may be configured to operate) as a source follower whose input terminal is connected to the floating diffusion node FD.

The select transistor SEL may be connected between the 0-th node NO and the column line CL. The select transistor SEL may operate (e.g., may be configured to operate) in response to the selection signal VSEL from the row driver 120. For example, the select transistor SEL may transfer the pixel signal PIX from the drive transistor DX to the column line CL in response to the selection signal VSEL of the logic high level.

In some example embodiments, an operation of transferring the voltage of the floating diffusion node FD to the column line CL through the drive transistor DX and the select transistor SEL and outputting the pixel signal PIX may be referred to as a “readout operation”. Also, an operation of turning on and turning off the transfer transistor TX such that the voltage of the floating diffusion node FD is decreased by the charges received from the photo diode PD may be referred to as a “shutter operation”. In addition, an operation of charging the floating diffusion node FD with the reset voltage through the reset transistor RST may be referred to as a “reset operation”. The image sensor device 100 according to some example embodiments may be configured to cause a readout operation, a shutter operation, and/or a reset operation to be performed at a pixel PX.

A voltage of the pixel signal PIX that the drive transistor DX outputs based on the voltage of the floating diffusion node FD being decreased through the shutter operation may be referred to as a “data voltage”.

Meanwhile, when the transfer transistor TX is turned on in response to the transfer signal VT for the purpose of performing the above shutter operation, the potential of the floating diffusion node FD may change. As such, the coupling may be caused between the floating diffusion node FD and a gate of the drive transistor DX. The coupling may affect the voltage level of the column line CL. To prevent the coupling, the select transistor SEL may be turned off while the transfer transistor TX is turned on.

That is, the select transistor SEL may be turned off while the shutter operation is performed; when the shutter operation ends, the transfer transistor TX may be turned off, and the select transistor SEL may be turned on. When the select transistor SEL is turned on, the pixel signal PIX generated by the shutter operation may be output to the column line CL. In some example embodiments, the voltage of the pixel signal PIX may be the data voltage.

FIG. 5B is a circuit diagram illustrating another example of one or more pixels in a pixel array 110 of FIG. 1 according to some example embodiments of the present inventive concepts. Referring to FIG. 5B, unlike FIG. 5A, the pixel PX may include two transfer transistors TX1 and TX2 and two photo diodes PD1 and PD2. Also, the pixel PX may include a dual conversion transistor DC connected between a second floating diffusion node FD2 and a first floating diffusion node FD1.

The first floating diffusion node FD1 or the second floating diffusion node FD2 may accumulate (or integrate) charges corresponding to the amount of incident light. While the transfer transistors TX1 and TX2 are respectively turned on by transfer signals VTa and VTb, the first floating diffusion node FD1 or the second floating diffusion node FD2 may accumulate (or integrate) charges supplied from the photo diodes PD1 and PD2. For example, a capacitance of the first floating diffusion node FD1 is depicted as a first capacitance CFD1.

The dual conversion transistor DC may be driven by a dual conversion signal VDC. When the dual conversion transistor DC is turned off, the capacitance of the first floating diffusion node FD1 may correspond to the first capacitance CFD1. In a normal environment, because the first floating diffusion node FD1 is not easily saturated, there is no need to increase the capacitance (i.e., CFD1) of the first floating diffusion node FD1. In some example embodiments, the dual conversion transistor DC may be turned off. When the dual conversion transistor DC is turned off, the image sensor device 100 may be referred to as operating in a high conversion gain (HCG) mode. For example, the image sensor device 100 may be configured to operate in an HCG mode based on causing the dual conversion transistor DC to be turned off, thereby electrically isolating the first and second diffusion nodes FD1 and FD2 from each other.

However, in a high-illuminance environment, the first floating diffusion node FD1 may be easily saturated. To prevent the above saturation, the dual conversion transistor DC may be turned on (e.g., the image sensor device 100 may be configured to cause the dual conversion transistor DC to be turned on) such that the first floating diffusion node FD1 and the second floating diffusion node FD2 are electrically connected. In some example embodiments, a capacitance of the floating diffusion nodes FD1 and FD2 may be increased to a sum of the first capacitance CFD1 and a second capacitance CFD2. When the dual conversion transistor DC is turned on, the image sensor device 100 may be referred to as operating in a low conversion gain (LCG) mode. For example, the image sensor device 100 may be configured to operate in an LCG mode based on causing the dual conversion transistor DC to be turned on, thereby electrically connecting the first and second diffusion nodes FD1 and FD2 to each other.

Operations of the reset transistor RST, the drive transistor DX, and the select transistor SEL and a voltage level change of the column line CL according to the turn-on/turn-off of the select transistor SEL are similar to those described with reference to FIG. 5A, and thus, additional description will be omitted to avoid redundancy.

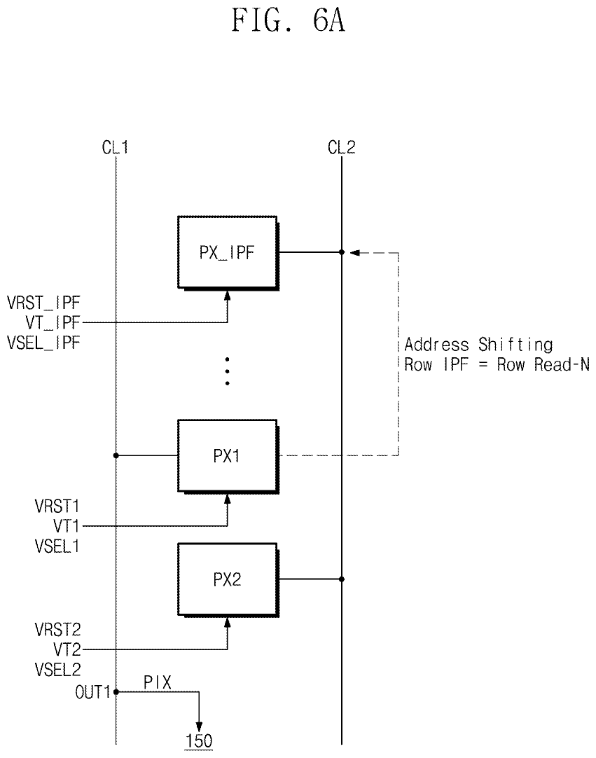

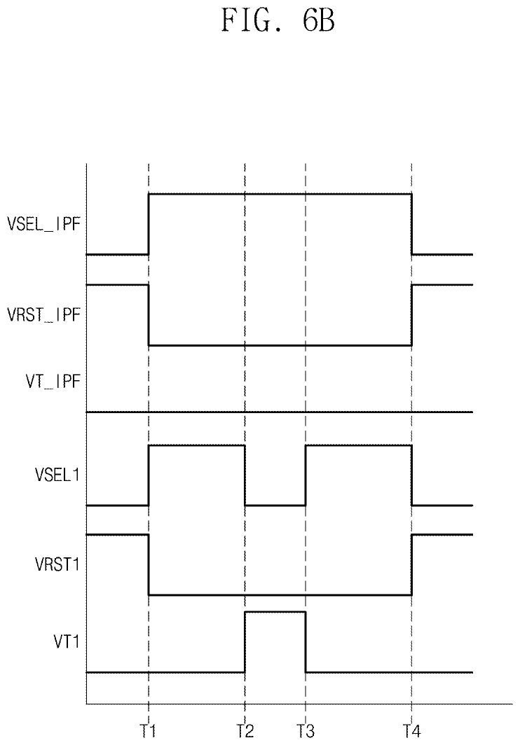

FIG. 6A is a diagram illustrating a pixel output level control operation according to a column line change, according to the present inventive concepts. The operation shown in FIG. 6A may be performed by an image sensor device including a pixel array according to any of the example embodiments, including for example the image sensor device 100 that includes the pixel array 110 as shown in FIG. 1. Accordingly, it will be understood that the image sensor device 100 may be configured to cause one or more pixels PX of the pixel array 110 to operate according to the operation as shown in FIG. 6A. Referring to FIGS. 1 and 6A, the pixel array 110 may include a plurality of pixels PX1, PX2, and PX_IPF, the first column line CL1, and the second column line CL2. The first pixel PX1 may be connected to the first column line CL1. The second pixel PX2 and the pixel PX_IPF may be connected to the second column line CL2, and the pixel PX_IPF (hereinafter referred to as an “IPF pixel”) may perform (e.g., may be configured to perform) a pixel output level control operation according to a column line change by the pixel array 110 according to some example embodiments of the present inventive concepts.

For brevity of illustration, two column lines CL1 and CL2 and three pixels PX1, PX2, and PX_IPF are illustrated. However, the present inventive concepts are not limited thereto. The pixel array may include more pixels and more column lines.

In some example embodiments, each of the pixels PX1, PX2, and PX_IPF may have the same structure as the pixel described with reference to FIG. 5A. However, the present inventive concepts are not limited thereto. For example, the pixels PX1, PX2, and PX_IPF may be implemented to have different structures.

For example, the first pixel PX1 may receive the first reset signal VRST1, the first transfer signal VT1, and the first selection signal VSEL1 from the row driver 120. The second pixel PX2 may receive the second reset signal VRST2, the second transfer signal VT2, and the second selection signal VSEL2. The IPF pixel PX_IPF may receive an IPF reset signal VRST_IPF, an IPF transfer signal VT_IPF, and an IPF selection signal VSEL_IPF from the row driver 120.

For example, to perform the readout operation on the first pixel PX1 during a first time period, the first selection signal VSEL1 may repeat a logic high state and a logic low state. In the case where the pixel output level control operation according to a column line change by the pixel array 110 of the present inventive concepts is not performed, during the first time period, the second selection signal VSEL2 and the IPF selection signal VSEL_IPF may be at the logic low level. As such, during the first time period, the second column line CL2 may be floated. After (e.g., subsequent to) the first time period, the second selection signal VSEL2 may be set to the logic high level to perform the readout operation on the second pixel PX2, and thus, the second column line CL2 may have an arbitrary voltage level.

When the select transistor SEL of the second pixel PX2 is turned on, a time (hereinafter referred to as a “settling time”) to set the voltage level of the second column line CL2 to the reset voltage may be required. Also, unlike the example illustrated in FIG. 6A, when the pixel array 110 includes more column lines, for example, when the readout operation of pixels connected to odd-numbered column lines ends and the readout operation of pixels connected to even-numbered column lines starts, the even-numbered column lines may have arbitrary different voltages. That is, settling times of the column lines may be different from each other. For this reason, the accuracy of correlated double sampling (CDS) for each column line may decrease, and a dynamic range of an image sensor may also decrease.

To prevent the above issue, according to the present inventive concepts, pixel output level control operation according to a column line change may be performed. For example, while the readout operation is performed on the first pixel PX1 (e.g., while the first selection signal VSEL1 toggles, during a same time period in which the first pixel PX1 outputs a pixel signal to the first column line CL1), the voltage level of the second column line CL2 (e.g., a first voltage applied to the second column line CL2) may be adjusted to a desired (e.g., particular) voltage level based on an operation of the IPF pixel PX_IPF that is located at a row different from that of the first pixel PX1, is connected to the second column line CL2, and does not perform the readout operation (e.g., already performs the readout operation, performs the readout operation prior to the first pixel PX1 performing the readout operation, prior to and while the first pixel PX1 performs the readout operation, etc.).

The IPF pixel PX_IPF may be a pixel that is located at a row (Row IPF) shifted from a row (Row Read) where the first pixel PX1 performing the readout operation is located, as much as the given number of rows “N” (Row IPF=Row Read−N), where “N” may be any integer. Below, the pixel output level control operation according to the column line change by the pixel array 110 of the present inventive concepts is referred to as an “in-pixel FLT (IPF) operation”.

FIG. 6B is a timing diagram for describing a pixel output level control operation according to a column line change of FIG. 6A according to some example embodiments of the present inventive concepts. The operation shown in FIG. 6B may be performed by an image sensor device including a pixel array according to any of the example embodiments, including for example the image sensor device 100 that includes the pixel array 110 as shown in FIG. 1. Accordingly, it will be understood that the image sensor device 100 may be configured to cause one or more pixels PX of the pixel array 110 to operate according to the operation as shown in FIG. 6B, for example based on causing the signals as shown in FIG. 6B to be at the voltage levels as shown in FIG. 6B. Referring to FIGS. 6A and 6B, before (e.g., prior to) a first point in time T1, the first reset signal VRST1 and the IPF reset signal VRST_IPF may be at the logic high level, and the first selection signal VSEL1 and the IPF selection signal VSEL_IPF may be at the logic low level. In some example embodiments, the reset transistors RST of the first pixel PX1 and the IPF pixel PX_IPF may be turned on, and the select transistors SEL of the first pixel PX1 and the IPF pixel PX_IPF may be turned off. As such, the first pixel PX1 and the IPF pixel PX_IPF may perform the reset operation. That is, the floating diffusion nodes FD of the first pixel PX1 and the IPF pixel PX_IPF may be charged with the reset voltage.

In time periods illustrated in FIG. 6B, the transfer transistor TX of the IPF pixel PX_IPF may be turned off in response to the IPF transfer signal VT_IPF of the logic low level.

At the first point in time T1, the first reset signal VRST1 may be at the logic low level. The reset transistor RST of the first pixel PX1 may be turned off in response to the first reset signal VRST1 of the logic low level.

From the first point in time T1 to a second point in time T2, the first selection signal VSEL1 may be set to the logic high level to perform the readout operation on the first pixel PX1. As the select transistor SEL of the first pixel PX1 is turned on in response to the first selection signal VSEL1, the first pixel PX1 may output the pixel signal PIX having an output voltage OUT1 to the multiplexer unit 150 through the first column line CL1 and the active load circuit 130. In some example embodiments, the output voltage OUT1 may be the reset voltage.

Also, to start the IPF operation of the IPF pixel PX_IPF at the first point in time T1, the IPF reset signal VRST_IPF may transition to the logic low level, and the IPF selection signal VSEL_IPF may transition to the logic high level. The reset transistor RST of the IPF pixel PX_IPF may be turned off in response to the IPF reset signal VRST_IPF of the logic low level. The select transistor SEL of the IPF pixel PX_IPF may be turned on in response to the IPF selection signal VSEL_IPF of the logic high level.

In some example embodiments, the IPF pixel PX_IPF may adjust the voltage level of the second column line CL2 (e.g., the magnitude of the voltage applied to the second column line CL2) through the select transistor SEL. In some example embodiments, the voltage level of the second column line CL2 may be adjusted based on the voltage level of the floating diffusion node FD which has been reset of the IPF pixel PX_IPF.

Afterwards, from the second point in time T2 to a third point in time T3, the first selection signal VSEL1 may be at the logic low level, and the first transfer signal VT1 may be at the logic high level. The select transistor SEL of the first pixel PX1 may be turned off in response to the first selection signal VSEL1 of the logic low level. As the transfer transistor TX of the first pixel PX1 is turned on in response to the first transfer signal VT1 of the logic high level, the charges may be transferred from the photo diode PD of the first pixel PX1 to the floating diffusion node FD. In some example embodiments, the voltage of the floating diffusion node FD of the first pixel PX1 may decrease.

The IPF reset signal VRST_IPF of the logic low level and the IPF selection signal VSEL_IPF of the logic high level may be continuously input to the IPF pixel PX_IPF. As such, the select transistor SEL of the IPF pixel PX_IPF may maintain the turn-on state. That is, from the second point in time T2 to the third point in time T3, the IPF pixel PX_IPF may continue to perform the IPF operation on the second column line CL2.

Afterwards, to perform the readout operation on the first pixel PX1, from the third point in time T3 to a fourth point in time T4, the first selection signal VSEL1 may be at the logic high level, and the first transfer signal VT1 may be at the logic low level. The transfer transistor TX of the first pixel PX1 may be turned off in response to the first transfer signal VT1 of the logic low level.

The select transistor SEL of the first pixel PX1 may be turned on in response to the first selection signal VSEL of the logic high level. As such, the first pixel PX1 may output the pixel signal PIX having the output voltage OUT1 to the multiplexer unit 150 through the first column line CL1 and the active load circuit 130. In some example embodiments, the output voltage OUT1 may be the data voltage.

The IPF reset signal VRST_IPF of the logic low level and the IPF selection signal VSEL_IPF of the logic high level may be continuously input to the IPF pixel PX_IPF. As such, the select transistor SEL of the IPF pixel PX_IPF may maintain the turn-on state. That is, from the third point in time T3 to the fourth point in time T4, the IPF pixel PX_IPF may continue to perform the IPF operation on the second column line CL2.

Afterwards, at the fourth point in time T4, the first reset signal VRST1 may be set to the logic high level, and the first selection signal VSEL1 may be set to the logic low level. As the reset transistor RST of the first pixel PX1 is turned on in response to the first reset signal VRST1 of the logic high level, the first pixel PX1 may perform the reset operation. Also, although not illustrated in FIG. 6B, the second selection signal VSEL2 may be set to the logic high level to perform the readout operation on the second pixel PX2. The select transistor SEL of the second pixel PX2 may be turned on in response to the second selection signal VSEL2 of the logic high level. That is, at the fourth point in time T4, the readout operation of the first pixel PX1 may end, and the readout operation of the second pixel PX2 may start.

Also, as the readout operation of the first pixel PX1 ends at the fourth point in time T4, the IPF selection signal VSEL_IPF may transition to the logic low level, and the IPF reset signal VRST_IPF may transition to the logic high level. As the select transistor SEL of the IPF pixel PX_IPF is turned off in response to the IPF selection signal VSEL_IPF of the logic low level, the IPF operation of the second column line CL2 may end.

In other words, the readout operation of the first pixel PX1 may be repeatedly performed from the first point in time T1 to the fourth point in time T4. The first selection signal VSEL1 may toggle from the first point in time T1 to the fourth point in time T4. The IPF operation of the IPF pixel PX_IPF may be performed until the readout operation of the first pixel PX1 ends. That is, from the first point in time T1 to the fourth point in time T4, the voltage level of the second column line CL2 may be adjusted based on the voltage level of the floating diffusion node FD which has been reset of the IPF pixel PX_IPF. Accordingly, the second column line CL2 may not be floated from the first point in time T1 to the fourth point in time T4. According to the above description, when the readout operation of the second pixel PX2 starts at the fourth point in time T4, the second column line CL2 may have the voltage level previously adjusted by the IPF operation, and thus, the settling time of the second column line CL2 may not be required or may be reduced or minimized. As a result, the difference between respective settling times of different columns (e.g., CL1, CL2, etc.) may be reduced, minimized, or eliminated, and thus the accuracy of correlated double sampling (CDS) for each column line may increase, and a dynamic range of an image sensor may also increase, based on the IPF pixel PX_IPF connected to one or more column lines performing one or more IPF operations (e.g., outputting a pixel signal during a certain time period that precedes and overlaps a time period where a pixel at a different row and a same column outputting a separate pixel signal to a preceding column line).

That is, according to some example embodiments of the present inventive concepts, while a selection signal (e.g., VSEL1) of a specific row toggles to perform the readout operation on the specific row, voltage levels of column lines that are not connected to pixels performing the readout operation may be adjusted based on operations of pixels located at a row where the readout operation is not performed. The voltage level adjustment operation may be referred to as an “IPF operation”.

As the image sensor device 100 uses the IPF operation, without an additional circuit, voltage levels of column lines where the readout operation are to be performed may be controlled to have a specific voltage level when a location of column lines connected to pixels where the readout operation is performed is changed from an odd-numbered location to an even-numbered location or from an even-numbered location to an odd-numbered location. In some example embodiments, the specific voltage level may be determined based on (e.g., may be based on) a voltage of a floating diffusion node which has been reset of a pixel where the IPF operation is performed.

In some example embodiments, the voltage level of the IPF reset signal VRST_IPF of the logic high level, which is input to the IPF pixel PX_IPF before the first point in time T1, may be lower than the voltage level of the IPF reset signal VRST_IPF of the logic high level, which is input to the IPF pixel PX_IPF after the fourth point in time T4.

In some example embodiments, the voltage level of the floating diffusion node FD which has been reset of the IPF pixel PX_IPF before the first point in time T1 may be lower than the voltage level of the floating diffusion node FD which has been reset of the IPF pixel PX_IPF after the fourth point in time T4. After the fourth point in time T4, when the IPF operation of the IPF pixel PX_IPF is performed, the voltage level of the second column line CL2 by the IPF operation may be adjusted to have a voltage level higher than that at the fourth point in time T4.

In other words, in some example embodiments, the image sensor device 100 may control the voltage level of the reset signal VRST_IPF of the logic high level, which is input to a pixel performing the IPF operation. That is, the voltage level of the column line, which is adjusted by the IPF operation, may be controlled.

The timing of the readout operation and the IPF operation of the pixel array 110 according to some example embodiments of the present inventive concepts is described with reference to FIG. 6B, but the present inventive concepts are not limited thereto. For example, the timing of signals may be modified depending on the way to implement (e.g., depending based on the structure of the pixel array 110 and/or the timing of operation of the pixels PX thereof to output pixel signals).

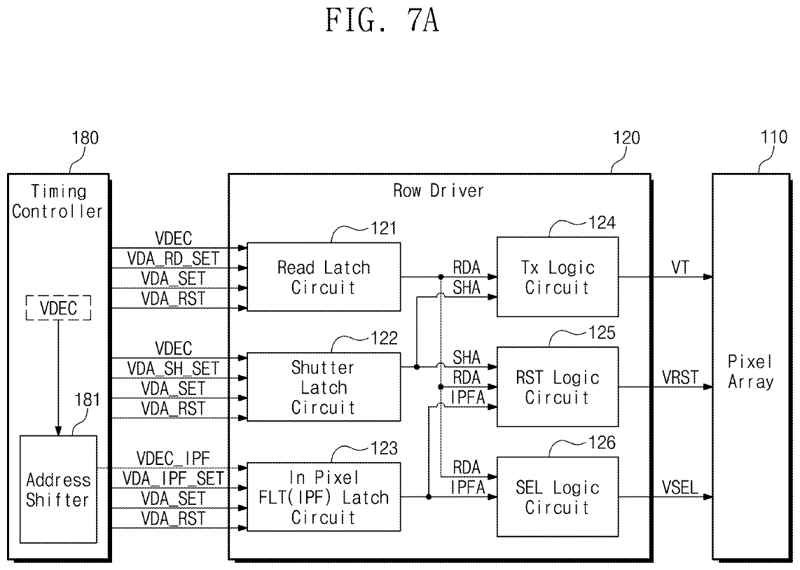

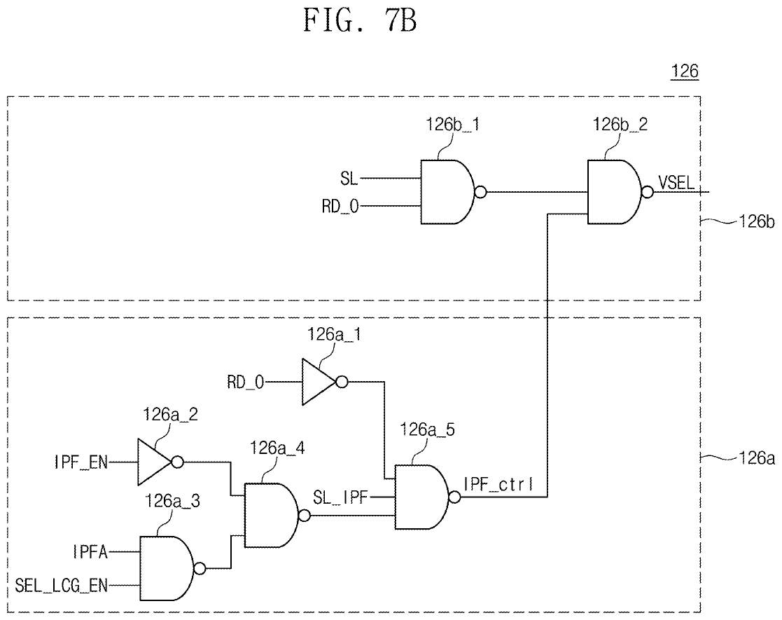

FIG. 7A is a diagram illustrating an example of a configuration of a row driver of FIG. 1 according to some example embodiments of the present inventive concepts. As described with reference to FIG. 1, under control of the timing controller 180, the row driver 120 may provide the pixel array 110 with the transfer signal VT, the reset signal VRST, and the selection signal VSEL for selecting and driving a row of the pixel array 110.

The row driver 120 may include a read latch circuit 121, a shutter latch circuit 122, an in-pixel FLT (IPF) latch circuit 123, a transfer (TX) logic circuit 124, a reset (RST) logic circuit 125, and a selection (SEL) logic circuit 126. Referring to FIG. 2, the pixel array 110 may be implemented on the first semiconductor substrate SD1, and the row driver 120 and the timing controller 180 may be implemented on the second semiconductor substrate SD2.

The latch circuits 121, 122, and 123 may store addresses, which are generated by the timing controller 180, based on control signals provided from the timing controller 180 and may provide the addresses to the logic circuits 124, 125, and 126. The logic circuits 124, 125, and 126 may control the pixel array 110 based on the addresses provided from the latch circuits 121, 122, and 123.

The timing controller 180 may generate a vertical decoding signal VDEC and may provide the vertical decoding signal VDEC to the read latch circuit 121 and the shutter latch circuit 122. For example, the vertical decoding signal VDEC may indicate a row address that the read latch circuit 121 and the shutter latch circuit 122 will store (i.e., an address of a row at which the readout operation and the shutter operation will be performed).

The timing controller 180 may include the address shifter 181. The address shifter 181 may generate an IPF vertical decoding signal VDEC_IPF indicating a row address shifted from a row address corresponding to the vertical decoding signal VDEC as much as the given number of rows.

For example, the IPF vertical decoding signal VDEC_IPF may indicate a row address that the IPF latch circuit 123 will store (i.e., an address of a row at which the IPF operation will be performed). In other words, the address of the row at which the IPF operation will be performed may be an address shifted from the address of the row at which the readout operation will be performed, as much as the given number of rows. For example, a row of the pixel array 110, at which the IPF operation will be performed, may be one of the rows of the pixel array 110, at which the readout operation is already completed. In some example embodiments, a pixel located at the row of the pixel array 110 at which the IPF operation will be performed may be a pixel connected to a column line different from a column line to which the pixel located at the row of the pixel array 110 at which the readout operation will be performed is connected.

Also, the timing controller 180 may generate latch set signals VDA_RD_SET, VDA_SH_SET, and VDA_IPF_SET for activating an operation in which the latch circuits 121, 122, and 123 store and maintain addresses (in other words, an operation of determining whether to store and maintain the provided addresses). That is, when the latch circuits 121, 122, and 123 of the present inventive concepts are not provided with the activated latch set signals VDA_RD_SET, VDA_SH_SET, and VDA_IPF_SET, even though the vertical decoding signal VDEC or the IPF vertical decoding signal VDEC_IPF is provided thereto, the latch circuits 121, 122, and 123 may fail to store relevant row addresses.

In addition, the timing controller 180 may generate a latch control signal VDA_SET and a latch reset signal VDA_RST for controlling operations of the latch circuits 121, 122, and 123. The latch control signal VDA_SET may allow the latch circuits 121, 122, and 123 to store and maintain a signal (e.g., a row address that the vertical decoding signal VDEC or the IPF vertical decoding signal VDEC_IPF indicates), and the latch reset signal VDA_RST may allow the latch circuits 121, 122, and 123 to be reset.

As described above, for the latch circuits 121, 122, and 123 to store and maintain signals in response to the latch control signal VDA_SET, first, the latch circuits 121, 122, and 123 have to be provided with the activated latch set signals VDA_RD_SET, VDA_SH_SET, and VDA_IPF_SET.

The read latch circuit 121 may store and maintain an address (hereinafter referred to as a “readout address”) of a row of the pixel array 110, at which the readout operation will be performed, during a given time, and the shutter latch circuit 122 may store and maintain an address (hereinafter referred to as a “shutter address”) of a row of the pixel array 110, at which the shutter operation will be performed, during a given time. Both the read latch circuit 121 and the shutter latch circuit 122 may be provided with the vertical decoding signal VDEC.

In detail, the read latch circuit 121 may store and maintain a readout address RDA indicated by the vertical decoding signal VDEC in response to the activated read latch set signal VDA_RD_SET and the activated latch control signal VDA_SET, and the shutter latch circuit 122 may store and maintain a shutter address SHA indicated by the vertical decoding signal VDEC in response to the activated shutter latch set signal VDA_SH_SET and the activated latch control signal VDA_SET.

After the given time passes, the read latch circuit 121 and the shutter latch circuit 122 may be initialized in response to the latch reset signal VDA_RST. The read latch circuit 121 may provide the readout address RDA to the logic circuits 124, 125, and 126, and the shutter latch circuit 122 may provide the shutter address SHA to the transfer logic circuit 124 and the reset logic circuit 125.

The IPF latch circuit 123 may store and maintain an address (hereinafter referred to as an “IPF address”) of a row of the pixel array 110, at which the IPF operation will be performed, during the given time. The IPF latch circuit 123 may be provided with the IPF vertical decoding signal VDEC_IPF. In detail, the IPF latch circuit 123 may store and maintain an IPF address IPFA indicated by the IPF vertical decoding signal VDEC_IPF in response to the activated IPF latch set signal VDA_IPL_SET and the activated latch control signal VDA_SET. After the given time passes, the IPF latch circuit 123 may be initialized in response to the latch reset signal VDA_RST. The IPF latch circuit 123 may provide the IPF address IPFA to the reset logic circuit 125 and the selection logic circuit 126.

The transfer logic circuit 124 may provide the transfer signal VT to a pixel located at a row of the pixel array 110, at which the readout operation or the shutter operation will be performed, based on the readout address RDA or the shutter address SHA.

The reset logic circuit 125 may provide the reset signal VRST to a pixel located at a row at which the readout operation, the shutter operation, or the IPF operation will be performed, based on the readout address RDA, the shutter address SHA, or the IPF address IPFA.

The selection logic circuit 126 may provide the selection signal VSEL to a pixel located at a row at which the readout operation or the IPF operation will be performed, based on the readout address RDA or the IPF address IPFA. For example, the readout address RDA and the IPF address IPFA corresponding to the same row may be simultaneously provided to the selection logic circuit 126. In some example embodiments, the selection logic circuit 126 may be configured to first output the selection signal VSEL associated with the readout operation and to then output the selection signal VSEL associated with the IPF operation.

FIG. 7B is a logic circuit diagram illustrating an example of a partial configuration of a selection logic circuit of FIG. 7A in detail according to some example embodiments of the present inventive concepts. Referring to FIG. 7B, the selection logic circuit 126 of FIG. 7A may include an IPF control signal generation circuit 126a and a selection signal generation circuit 126b.

The IPF control signal generation circuit 126a may include first and second inverters 126a_1 and 126a_2 and first to third NAND gates 126a_3 to 126a_5. The first inverter 126a_1 may receive a readout control signal RD_O and may invert the readout control signal RD_O so as to be output to the third NAND gate 126a_5. The readout control signal RD_O may include information for controlling the readout address RDA and the readout operation.

The second inverter 126a_2 may receive an IPF enable signal IPF_EN from the outside and may invert the IPF enable signal IPF_EN so as to be output to the second NAND gate 126a_4. The IPF enable signal IPF_EN may include information about whether the image sensor device 100 performs the IPF operation.

In some example embodiments, the IPF enable signal IPF_EN may include information indicating that the image sensor device 100 does not perform the IPF operation. In some example embodiments, even though the IPF address IPFA is received, the selection logic circuit 126 may not output the selection signal VSEL for performing the IPF operation.

The first NAND gate 126a_3 may receive the IPF address IPFA and a mode selection signal SEL_LCG_EN. The mode selection signal SEL_LCG_EN may include information about whether to operate in the HCG mode or the LCG mode when the readout operation is performed. For example, each of the pixels PX of the pixel array 110 of FIG. 7A may include the dual conversion transistor DC like the pixel structure described with reference to FIG. 5B.

The second NAND gate 126a_4 may receive an output signal of the first inverter 126a_1 and an output signal of the first NAND gate 126a_3. The second NAND gate 126a_4 may output a signal, which is based on the IPF enable signal IPF_EN, the IPF address IPFA, and the mode selection signal SEL_LCG_EN, to the third NAND gate 126a_5.

The third NAND gate 126a_5 may receive an output signal of the second NAND gate 126a_4, an output signal of the second inverter 126a_2, and an IPF pulse signal SL_IPF and may output an IPF control signal IPF_ctrl to the selection signal generation circuit 126b. The IPF pulse signal SL_IPF may be a pulse signal that may be required to generate the IPF control signal IPF_ctrl. The IPF control signal IPF_ctrl may include information about whether to perform the IPF operation, an address at which the IPF operation is to be performed, an address at which the readout operation is to be performed, and a mode to perform the readout operation.

The selection signal generation circuit 126b may include a first NAND gate 126b_1 and a second NAND gate 126b_2. The first NAND gate 126b_1 may receive a selection pulse signal SL and the readout control signal RD_O. The selection pulse signal SL may be a pulse signal that is basically required to generate the selection signal VSEL. The second NAND gate 126b_2 may receive an output signal of the first NAND gate 126b_1 and the IPF control signal IPF_ctrl and may output the selection signal VSEL. The selection signal VSEL may be generated based on the readout address RDA, the IPF address IPFA, a mode to perform the readout operation, whether the IPF operation is performed, etc.

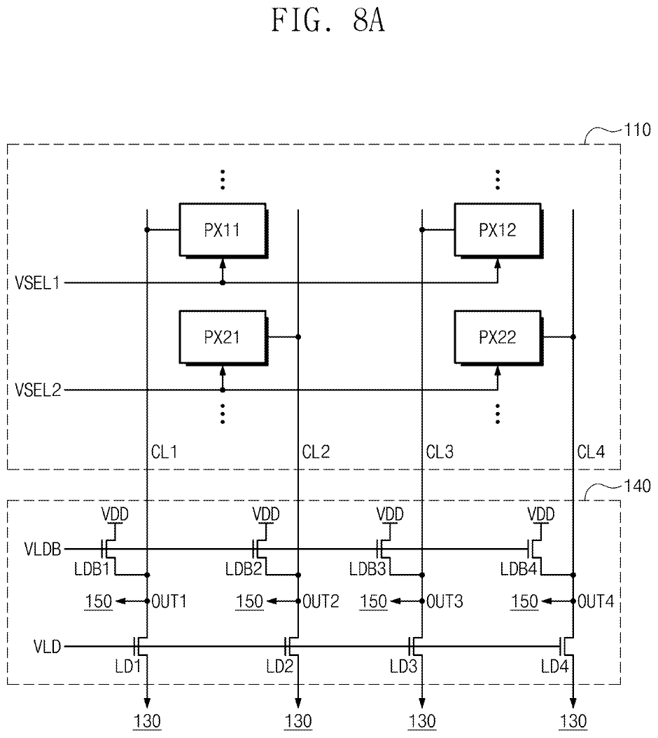

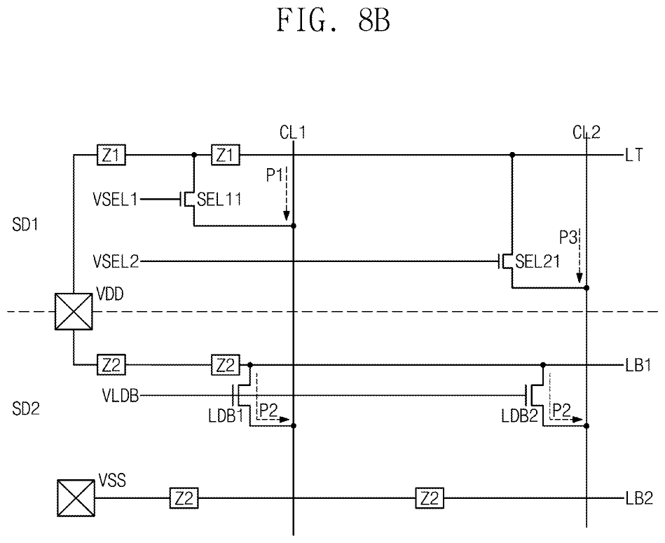

FIG. 8A is a circuit diagram illustrating a line disconnection circuit of FIG. 1 according to some example embodiments of the present inventive concepts. Referring to FIGS. 1 and 8A, the image sensor device 100 may include the pixel array 110 and the line disconnection circuit 140. The image sensor device 100 according to the present inventive concepts may perform the IPF operation as described with reference to FIGS. 6A and 6B.

In some example embodiments, each of the pixels PX11, PX12, PX21, and PX22 included in the pixel array 110 may have the same structure as the pixel described with reference to FIG. 5A. However, the present inventive concepts are not limited thereto. For example, the pixels may be implemented to have a structure different from the above structure.

For example, while the image sensor device 100 performs the readout operation and the shutter operation on the pixels PX11 and PX12 connected to the odd-numbered column lines CL1 and CL3, the image sensor device 100 may turn on the select transistors SEL of IPF pixels connected to the even-numbered column lines CL2 and CL4 such that the even-numbered column lines CL2 and CL4 are not floated.

In some example embodiments, even though the readout operation of pixels located at the first row ends and the select transistors SEL of pixels located at the second row are turned on (i.e., even though column lines connected to pixels where the readout operation and the shutter operation are to be performed are switched from the odd-numbered column lines CL1 and CL3 to the even-numbered column lines CL2 and CL4), the additional settling time for the even-numbered column lines CL2 and CL4 may not be required.

However, when the image sensor device 100 does not include the line disconnection circuit 140, for example, while the image sensor device 100 performs the shutter operation on the pixels PX11 and PX12 located at the first row, the select transistors SEL included in the pixels PX11 and PX12 connected to the first column line CL1 and the third column line CL3 may be turned off in response to the first selection signal VSEL1 of the logic low level.

In some example embodiments, while the shutter operation of the pixels PX11 and PX12 located at the first row is performed, the second column line CL2 and the fourth column line CL4 may not be floated by the IPF operation. In contrast, the first column line CL1 and the third column line CL3 may be floated and thus may have an arbitrary voltage level. In some example embodiments, the first column line CL1 and the third column line CL3 may have arbitrary different voltage levels.

Meanwhile, the select transistors SEL of the pixels PX11 and PX12 located at the first row may be turned on to perform the readout operation on the pixels PX11 and PX12 located at the first row after the shutter operation. In some example embodiments, for example, when the voltage level of the first column line CL1 is changed from the above arbitrary voltage level to the data voltage generated by the shutter operation, the accuracy of correlated double sampling (CDS) may decrease. As such, the settling time when the voltage level of the first column line CL1 is changed from the arbitrary voltage level to the reset voltage may be required after the shutter operation.

Also, when arbitrary voltage levels of the first column line CL1 and the third column line CL3 are different from each other, the settling time of the first column line CL1 and the settling time of the third column line CL3 may be different from each other. For this reason, the accuracy of correlated double sampling (CDS) for each of the column lines CL1 and CL3 may decrease, and a dynamic range of an image sensor may also decrease.

To reduce, minimize, or prevent the above issue, the image sensor device 100 of the present inventive concepts may include the line disconnection circuit 140. The line disconnection circuit 140 may include a plurality of transistors LD1 to LD4 and LDB1 to LDB4 for adjusting voltage levels of the column lines CL1 to CL4 to a desired voltage level.

The transistors LD1 to LD4 may be turned on or turned off in response to a line disconnection signal VLD, and the transistors LDB1 to LDB4 may be turned on or turned off in response to an inverted line disconnection signal VLDB. For example, the line disconnection signal VLD and the inverted line disconnection signal VLDB may be provided under control of the timing controller 180 of FIG. 1.

For example, voltage levels of the line disconnection signal VLD and the inverted line disconnection signal VLDB may be complementary. That is, when the voltage level of the line disconnection signal VLD is the high level, the voltage level of the inverted line disconnection signal VLDB may be the low level; in contrast, when the voltage level of the line disconnection signal VLD is the low level, the voltage level of the inverted line disconnection signal VLDB may be the high level.

For example, first ends of the transistors LD1 to LD4 may be connected to the active load circuit 130, and second ends thereof may be connected to the column lines CL1 to CL4. Also, first ends of the transistors LDB1 to LDB4 may be supplied with the power supply voltage VDD, and second ends thereof may be connected to the column lines CL1 to CL4.

While the readout operation is performed on pixels (e.g., PX11 and PX12) located at an arbitrary row of the pixel array 110, the transistors LD1 to LD4 may be turned on in response to the line disconnection signal VLD of the high level, and the transistors LDB1 to LDB4 may be turned off in response to the inverted line disconnection signal VLDB of the low level. In some example embodiments, the pixel signals whose levels are identical as levels of the output voltages OUT1 to OUT4 may be transferred to the multiplexer unit 150, and voltage levels of the column lines CL1 to CL4 may not be separately adjusted.

The line disconnection circuit 140 may adjust voltage levels of the column lines CL1 to CL4 to a desired voltage level such that the voltage levels of the column lines CL1 to CL4 are equally set before the select transistors SEL are turned on. For example, the voltage levels of the column lines CL1 to CL4 may correspond to the levels of the output voltages OUT1 to OUT4. When the select transistors SEL of pixels are turned off, the transistors LDB1 to LDB4 may be turned on in response to the inverted line disconnection signal VLDB of the high level.

The turned-on transistors LDB1 to LDB4 may adjust the voltage levels of the column lines CL1 to CL4 to a specific voltage (e.g., the power supply voltage VDD) before the select transistors SEL of pixels located at a row where the readout operation is to be performed are turned on. In some example embodiments, the transistors LD1 to LD4 may be turned off in response to the line disconnection signal VLD of the low level.

That is, while the select transistors SEL of the pixels are turned off, the line disconnection circuit 140 may turn on the transistors LDB1 to LDB4 such that the column lines CL1 to CL4 are not floated. As such, for example, when the readout operation is performed on pixels located at an arbitrary row after the shutter operation, the additional settling time for column lines connected to the pixels of the row where the readout operation is performed may not be required, or may be reduced or minimized, thereby improving performance of the image sensor device 100.

As described above, the line disconnection circuit 140 may control the voltage levels of the column lines CL1 to CL4. However, as described with reference to FIG. 2, because the line disconnection circuit 140 is implemented on the second semiconductor substrate SD2 and the pixel array 110 is implemented on the first semiconductor substrate SD1, the function that the line disconnection circuit 140 adjusts the voltage levels of the column lines CL1 to CL4 may not be uniform due to a difference between processes of treating semiconductor substrates.

Also, because a distance between pixels of each row and the transistors LDB1 to LDB4 differs for each row, an IR drop and an RC delay that are caused by line resistances and line capacitances of the column lines CL1 to CL4 when the transistors LDB1 to LDB4 charges the column lines CL1 to CL4 may differ for each row. This may mean that it is difficult to accurately adjust the voltage levels of the column lines CL1 to CL4.

Meanwhile, even though the image sensor device 100 including the line disconnection circuit 140 does not perform the IPF operation according to some example embodiments of the present inventive concepts, the image sensor device 100 may adjust a voltage level of a column line different from a column line connected to a pixel where the readout operation is performed.

For example, to perform the shutter operation on the pixels PX11 and PX12 located at the first row, the transistors LDB1 to LDB4 of the line disconnection circuit 140 may be turned on in a period where the select transistors SEL of the pixels PX11 and PX12 located at the first row are turned off. As such, the line disconnection circuit 140 may also adjust the voltage levels of the second column line CL2 and the fourth column line CL4 that are not connected to the pixels PX11 and PX12 located at the first row.

However, even in some example embodiments, the voltage level adjustment function of the line disconnection circuit 140 may be reduced by the process difference of the semiconductor substrates and the IR drop and the RC delay differently caused for each row.

Also, the line disconnection circuit 140 may adjust voltage levels of column lines only in a period where the select transistors SEL of pixels (e.g., PX11 and PX12) where the readout operation is performed are turned off. As the image sensor device 100 operates at high speed, a period where the select transistors SEL are turned off may become shorter. In some example embodiments, the voltage levels of the column lines may not be sufficiently adjusted by the line disconnection circuit 140.

FIG. 8B is a diagram for describing an issue of a line disconnection circuit of FIG. 8A in detail according to some example embodiments of the present inventive concepts. Referring to FIGS. 8A and 8B, a select transistor SEL11 included in the pixel PX11 located at the first row may be connected to the first column line CL1, and a select transistor SEL21 included in the pixel PX21 located at the second row may be connected to the second column line CL2. The transistors LDB1 and LDB2 of the line disconnection circuit 140 may be respectively connected to the column lines CL1 and CL2.

Meanwhile, the select transistors SEL11 and SEL21 included in the pixel array 110 may be formed on the first semiconductor substrate SD1, and the transistors LDB1 and LDB2 included in the line disconnection circuit 140 may be formed on the second semiconductor substrate SD2.

A conductive line LT that is formed in the first semiconductor substrate SD1 and supplies the power supply voltage VDD to the first semiconductor substrate SD1 may include first impedances Z1. Conductive lines LB1 and LB2 that are formed in the second semiconductor substrate SD2 and supply the power supply voltage VDD and a ground voltage VSS to the second semiconductor substrate SD2 may include second impedances Z2. The magnitude of the first impedance Z1 and the magnitude of the second impedance Z2 may be different from each other due to the process difference of the first semiconductor substrate SD1 and the second semiconductor substrate SD2.

Meanwhile, for example, when the readout operation is performed on the pixel PX11 located at the first row and connected to the first column line CL1, the select transistor SEL11 may be turned on in response to the first selection signal VSEL1 of the logic high level, and the transistors LDB1 and LDB2 of the line disconnection circuit 140 may be turned off. As such, a current path P1 may be formed in the first semiconductor substrate SD1.

After the readout operation is performed on the pixel PX11 located at the first row and connected to the first column line CL1, the select transistor SEL11 may be turned off in response to the first selection signal VSEL1 of the logic low level. In some example embodiments, the transistors LDB1 and LDB2 of the line disconnection circuit 140 may be turned on in response to the inverted line disconnection signal VLDB of the logic high level. As such, a current path P2 may be formed in the second semiconductor substrate SD2.

Afterwards, when the readout operation is performed on the pixel PX21 located at the second row and connected to the second column line CL2, the select transistor SEL21 may be turned on in response to the second selection signal VSEL2 of the logic high level. As such, a current path P3 may be formed in the first semiconductor substrate SD1.

As described above, when a column line connected to a pixel where the readout operation is performed is changed, the locations where the current paths P1 to P3 are formed may be changed from the second semiconductor substrate SD2 to the first semiconductor substrate SD1 or from the first semiconductor substrate SD1 to the second semiconductor substrate SD2. When the current paths P1 to P3 are changed (e.g., when the switch from P2 to P3 is made), the fluctuations of a current may be caused due to a difference between the first impedance Z1 of the first semiconductor substrate SD1 and the second impedance Z2 of the second semiconductor substrate SD2.

In some example embodiments, the line disconnection circuit 140 may fail to adjust voltage levels of column lines (e.g., CL1 and CL2) with a constant current. That is, the voltage level adjustment function of the line disconnection circuit 140 may be reduced.

In contrast, the pixels of the pixel array 110 may be implemented on the same semiconductor substrate (e.g., the first semiconductor substrate SD1). As such, when the image sensor device 100 performs the IPF operation, the process of treating a semiconductor substrate may not affect the function of adjusting voltage levels of column lines.

Also, when the voltage levels of the column lines are adjusted by the IPF operation, a current path may be formed only in the first semiconductor substrate SD1, and thus, the above issue that the voltage level adjustment function is reduced due to the fluctuations of a current may not occur.

Also, the pixel array 110 may adjust voltage levels of column lines based on an operation of other pixels located at a row spaced therefrom the pixels on which the readout operation is being performed as much as a given distance, and thus, a location of a pixel may not affect the function of adjusting voltage levels of column lines. Accordingly, the IPF operation of the pixel array 110 may supplement a non-uniform operation of the line disconnection circuit 140.

Also, even while the readout operation is performed on an arbitrary row (i.e., while select transistors of pixels where the readout operation is performed are turned on), the IPF operation may adjust voltage levels of column lines not connected to the pixels where the readout operation is performed. As such, when the IPF operation is performed, it may be possible to adjust voltage levels of column lines during a relatively long time compared to the line disconnection circuit 140. Accordingly, even though the image sensor device 100 operates at high speed, a time taken to adjust voltage levels of column lines may be sufficiently secured.

In other words, when the image sensor device 100 performs the IPF operation, the operation of the line disconnection circuit 140, which is performed non-uniformly with regard to column lines not connected to pixels where the readout operation is performed, may be supplemented or replaced, thereby improving operational performance of the image sensor device 100.

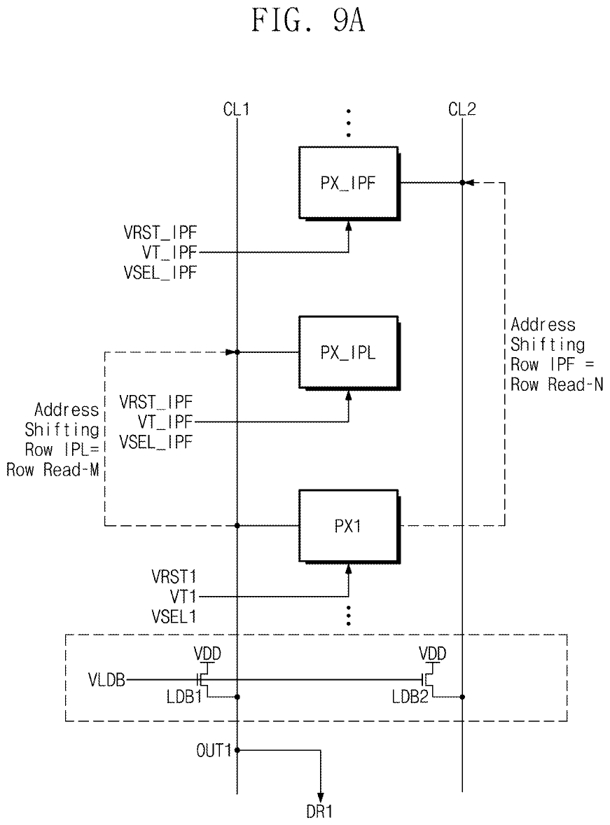

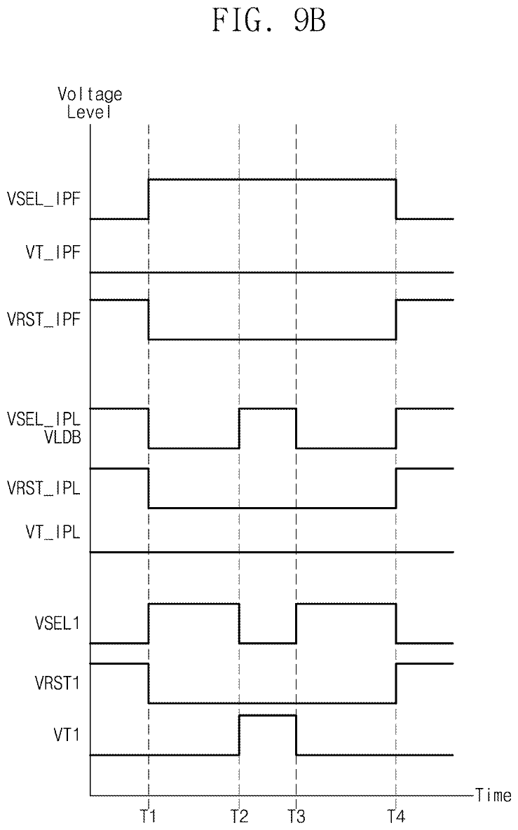

FIG. 9A is a diagram illustrating a pixel output level control operation including a line disconnection circuit according to some example embodiments of the present inventive concepts. The operation shown in FIG. 9A may be performed by an image sensor device including a pixel array according to any of the example embodiments, including for example the image sensor device 100 that includes the pixel array 110 as shown in FIG. 1. Referring to FIGS. 1 and 9A, the pixel array 110 may include a plurality of pixels PX1, PX_IPL, and PX_IPF, the first column line CL1, and the second column line CL2. The first pixel PX1 and the IPL pixel PX_IPL may be connected to the first column line CL1. The IPF pixel PX_IPF may be connected to the second column line CL2.

In some example embodiments, the pixels PX1, PX_IPL, and PX_IPF may have the same structure as the pixel described with reference to FIG. 5A. However, the present inventive concepts are not limited thereto. For example, the pixels PX1, PX_IPL, and PX_IPF may be implemented to have different structures.

For brevity of illustration, two column lines CL1 and CL2 and three pixels PX1, PX_IPL, and PX_IPF are illustrated. However, the present inventive concepts are not limited thereto. The pixel array may include more pixels and more column lines.

The operation of the IPF pixel PX_IPF is identical to that described with reference to FIGS. 6A and 6B. For example, while the readout operation and the shutter operation are performed on the first pixel PX1, the IPF pixel PX_IPF may perform the IPF operation such that the voltage level of the second column line CL2 is adjusted based on the voltage level of the floating diffusion node FD which has been reset of the IPF pixel PX_IPF.

As described with reference to FIG. 8A, the line disconnection circuit 140 may prevent the floating of column lines connected to pixels where the readout operation is performed, during the turn-off of the select transistors SEL of the pixels where the readout operation is performed.

For example, the readout operation may be repeatedly performed on the first pixel PX1. To perform the shutter operation on the first pixel PX1, the select transistor SEL of the first pixel PX1 may be turned off in response to a first select transistor VSEL1 of the low level. While the select transistor SEL of the first pixel PX1 is turned off, the transistors LDB1 and LDB2 of the line disconnection circuit 140 may be turned on in response to the inverted line disconnection signal VLDB of the logic high level. As such, the line disconnection circuit 140 may prevent the first column line CL1 from being floated during the turn-off of the select transistor SEL in the first pixel PX1.

However, even though the line disconnection circuit 140 adjusts the voltage of the first column line CL1 during the turn-off of the select transistor SEL in the first pixel PX1, as described with reference to FIG. 8A, the voltage adjustment function of the line disconnection circuit 140 associated with the first column line CL1 may be reduced due to the process difference of the first semiconductor substrate SD1 and the second semiconductor substrate SD2 and a location difference of pixel rows.

In some example embodiments, to supplement the reduction of the voltage adjustment function of the line disconnection circuit 140 associated with column lines (e.g., CL1) connected to pixels (e.g., PX1) where the readout operation is performed, the pixel output level control operation may be performed on the column lines where the readout operation of the pixel array 110 is performed. Below, the pixel output level control operation associated with a column line where the readout operation of the pixel array 110 is performed is referred to as an “in-pixel LDB (IPL) operation”.

The IPL operation may be performed by the IPL pixel PX_IPL. The IPL pixel PX_IPL may be a pixel that is connected to a column line (e.g., CL1) connected to a pixel (e.g., PX1) where the readout operation is performed and whose readout operation is already completed. For example, a pixel to perform the IPL operation may be a pixel located at a row Row_IPL shifted from a row Row_Read, at which a pixel to perform the readout operation is located, as much as the given number of rows “M”, (Row_IPL=Row_Read−M), where “M” may be any integer.

For example, the readout operation and the shutter operation may be performed on the first pixel PX1. To perform the shutter operation on the first pixel PX1, the select transistor SEL of the first pixel PX1 may be turned off in response to the first selection signal VSEL1 of the low level. In a period where the select transistor SEL of the first pixel PX1 is turned off, the select transistor SEL of the IPL pixel PX_IPL may be turned on in response to an IPL selection signal VSEL_IPL of the logic high level. In some example embodiments, the voltage level of the first column line CL1 may be adjusted by the select transistor SEL of the IPL pixel PX_IPL.

Afterwards, while the select transistor SEL of the first pixel PX1 is turned on in response to the first selection signal VSEL1 of the high level to perform the readout operation on the first pixel PX1, the select transistor SEL of the IPL pixel PX_IPL may be turned off in response to the IPL selection signal VSEL_IPL of the low level.

In other words, while the select transistor SEL of the first pixel PX1 is turned off where the readout operation is performed, the select transistor SEL of the IPL pixel PX_IPL may be turned on, and thus, the voltage level of the first column line CL1 may be adjusted. The voltage level of the first column line CL1 may be adjusted based on the voltage level of the floating diffusion node FD which has been reset of the IPL pixel PX_IPL.

The IPL operation may be performed under control of the row driver 120 (refer to FIG. 1) and the timing controller 180 (refer to FIG. 1). As the IPL operation is used, in a period where the select transistors SEL of pixels (e.g., PX1) where the readout operation is performed are turned off, the floating of column lines connected to the pixels (e.g., PX1) where the readout operation is performed may be prevented by using only transistors of a semiconductor substrate (e.g., SD1) where the pixel array 110 is formed. Accordingly, the IPL operation may supplement the reduction of the voltage adjustment function of the line disconnection circuit 140 associated with column lines (e.g., CL1) connected to the pixels (e.g., PX1) where the readout operation is performed.

That is, while the readout operation is repeatedly performed, the image sensor device 100 may prevent the floating of a column line (e.g., CL2) not connected to a pixel (e.g., PX1) where the readout operation is performed, by using the IPF operation. Also, in a period where select transistors of pixels where the readout operation is performed are turned off, the image sensor device 100 may prevent the floating of a column line (e.g., CL1) connected to a pixel (e.g., PX1) where the readout operation is performed, by using the IPL operation. In addition, the image sensor device 100 may supplement or replace the pixel output level control method of the line disconnection circuit 140 by using the IPF operation and the IPL operation.

In some example embodiments, the image sensor device 100 may selectively perform a method in which the voltage levels of the column lines CL1 and CL2 are adjusted by the line disconnection circuit 140, a method in which the voltage levels of the column lines CL1 and CL2 are adjusted by the IPL operation, and a method in which the voltage levels of the column lines CL1 and CL2 are adjusted by the IPF operation. For example, a register that is capable of enabling one of the three methods described above may be set by the timing controller 180.

FIG. 9B is a timing diagram for describing a pixel output level control operation of FIG. 9A according to some example embodiments of the present inventive concepts. The operation shown in FIG. 9B may be performed by an image sensor device including a pixel array according to any of the example embodiments, including for example the image sensor device 100 that includes the pixel array 110 as shown in FIG. 1. The operation of the IPF pixel PX_IPF is identical to that described with reference to FIGS. 6A and 6B. For example, the readout operation and the shutter operation may be repeatedly performed on the first pixel PX1 from the first point in time T1 to the fourth point in time T4.

In some example embodiments, from the first point in time T1 to the fourth point in time T4, the IPF selection signal VSEL_IPF may be at the logic high level, and the IPF reset signal VRST_IPF may be at the logic low level. As such, from the first point in time T1 to the fourth point in time T4, the IPF pixel PX_IPF may adjust the voltage level of the second column line CL2. The voltage level of the second column line CL2 may be determined based on the voltage level of the floating diffusion node FD which has been reset of the IPF pixel PX_IPF.

Because the IPF operation is described in detail with reference to FIGS. 6A and 6B, below, the IPL operation and the operation of the line disconnection circuit 140 will be described in detail.

Referring to FIGS. 9A and 9B, before the first point in time T1, the first reset signal VRST1 and an IPL reset signal VRST_IPL may be at the logic high level, and the first selection signal VSEL1 may be at the logic low level. In some example embodiments, the reset transistors RST of the first pixel PX1 and the IPL pixel PX_IPL may be turned on, and the select transistor SEL of the first pixel PX1 may be turned off. That is, the first pixel PX1 and the IPL pixel PX_IPL may perform the reset operation. Through the reset voltage, the floating diffusion nodes FD of the first pixel PX1 and the IPL pixel PX_IPL may be charged with the reset voltage.

Also, the inverted line disconnection signal VLDB may be at the logic high level. The transistors LDB1 and LDB2 of the line disconnection circuit 140 may be turned on in response to the inverted line disconnection signal VLDB of the logic high level, and thus, voltage levels of the first column line CL1 and the second column line CL2 may be adjusted by the line disconnection circuit 140.

At the first point in time T1, the first reset signal VRST1 may be at the logic low level. The reset transistor RST of the first pixel PX1 may be turned off in response to the first reset signal VRST1 of the logic low level.

To perform the readout operation on the first pixel PX1 from the first point in time T1 to the second point in time T2, the first selection signal VSEL1 may be set to the logic high level. As the select transistor SEL of the first pixel PX1 is turned on in response to the first selection signal VSEL1 of the logic high level, the first pixel PX1 may output the pixel signal PIX having the output voltage OUT1 to the multiplexer unit 150 through the first column line CL1 and the active load circuit 130. In some example embodiments, the output voltage OUT1 may be the reset voltage.

Also, the IPL reset signal VRST_IPL, the IPL selection signal VSEL_IPL, and the inverted line disconnection signal VLDB may be at the logic low level. The transistors LDB1 and LDB2 of the line disconnection circuit 140 may be turned off in response to the inverted line disconnection signal VLDB of the logic low level. Also, the select transistor SEL of the IPL pixel PX_IPL may be turned off in response to the IPL selection signal VSEL_IPL of the logic low level. In some example embodiments, voltages of the first and second column lines CL1 and CL2 may not be adjusted by the line disconnection circuit 140, and the IPL operation may not be performed by the IPL pixel PX_IPL.

Afterwards, from the second point in time T2 to the third point in time T3, the first selection signal VSEL1 may be at the logic low level, and the first transfer signal VT1 may be at the logic high level. The select transistor SEL of the first pixel PX1 may be turned off in response to the first selection signal VSEL1 of the logic low level. As the transfer transistor TX of the first pixel PX1 is turned on in response to the first transfer signal VT1 of the logic high level, the charges may be transferred from the photo diode PD of the first pixel PX1 to the floating diffusion node FD. In some example embodiments, the voltage of the floating diffusion node FD of the first pixel PX1 may decrease.

Meanwhile, the IPL selection signal VSEL_IPL and the inverted line disconnection signal VLDB may be at the logic high level. The transistors LDB1 and LDB2 of the line disconnection circuit 140 may be turned on in response to the inverted line disconnection signal VLDB of the logic high level, and thus, the voltage levels of the first column line CL1 and the second column line CL2 may be adjusted by the line disconnection circuit 140.

Also, as the select transistor SEL of the IPL pixel PX_IPL is turned on in response to the IPL selection signal VSEL_IPL of the logic high level, the IPL pixel PX_IPL may perform the IPL operation. The voltage level of the first column line CL1 may be adjusted by the IPL operation. The voltage level of the first column line CL1 may be adjusted based on the voltage level of the floating diffusion node FD which has been reset of the IPL pixel PX_IPL.

Afterwards, to perform the readout operation on the first pixel PX1, from the third point in time T3 to the fourth point in time T4, the first selection signal VSEL1 may be at the logic high level, and the first transfer signal VT1 may be at the logic low level. The transfer transistor TX of the first pixel PX1 may be turned off in response to the first transfer signal VT1 of the logic low level. As the select transistor SEL of the first pixel PX1 is turned on in response to the first selection signal VSEL1 of the logic high level, the first pixel PX1 may output the pixel signal PIX having the output voltage OUT1 to the multiplexer unit 150 through the first column line CL1 and the active load circuit 130. In some example embodiments, the output voltage OUT1 may be the data voltage.

Meanwhile, the IPL selection signal VSEL_IPL and the inverted line disconnection signal VLDB may be at the logic low level. The transistors LDB1 and LDB2 of the line disconnection circuit 140 may be turned off in response to the inverted line disconnection signal VLDB of the logic low level. Also, the select transistor SEL of the IPL pixel PX_IPL may be turned off in response to the IPL selection signal VSEL_IPL of the logic low level. In some example embodiments, voltages of the first and second column lines CL1 and CL2 may not be adjusted by the line disconnection circuit 140, and the IPL operation may not be performed by the IPL pixel PX_IPL.

Afterwards, at the fourth point in time T4, the first selection signal VSEL1 may transition to the logic low level, and thus, the select transistor SEL of the first pixel PX1 may be turned off. Also, as the first reset signal VRST1 transitions to the logic high level, the reset transistor RST of the first pixel PX1 may be turned on. That is, the first pixel PX1 may perform the reset operation.

Also, as the readout operation of the first pixel PX1 ends at the fourth point in time T4, the inverted line disconnection signal VLDB may transition to the logic high level, and the IPL reset signal VRST_IPL may transition to the logic high level. As such, the IPL pixel PX_IPL may perform the reset operation, and the voltage levels of the first and second column lines CL1 and CL2 may be adjusted by the line disconnection circuit 140.

The timing of the readout operation, the IPF operation, and the IPL operation in the pixel array 110 according to some example embodiments of the present inventive concepts is described with reference to FIG. 9B, but the present inventive concepts are not limited thereto. For example, the timing of signals may be modified depending on the way to implement (e.g., depending based on the structure of the pixel array 110 and/or the timing of operation of the pixels PX thereof to output pixel signals).

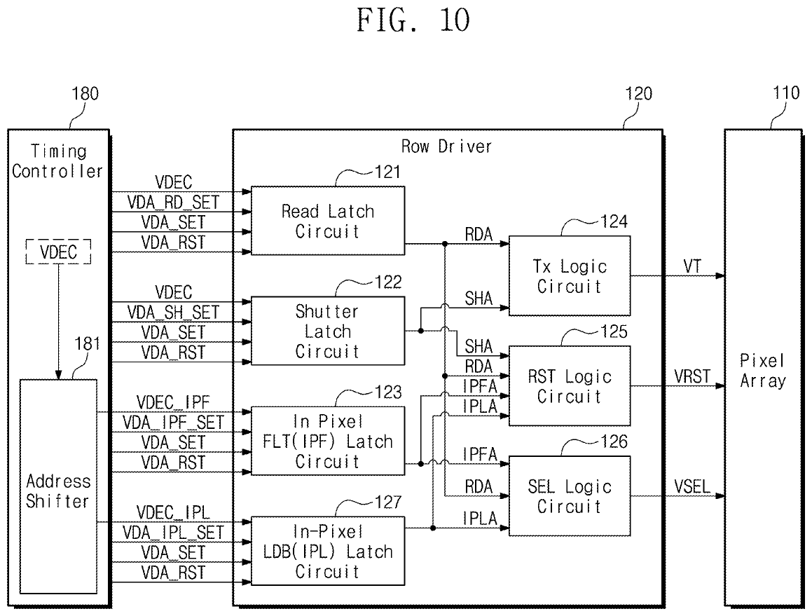

FIG. 10 is a diagram illustrating an example of a configuration of a row driver of FIG. 1 according to some example embodiments of the present inventive concepts. FIG. 10 will be described with reference to FIGS. 7A and 7B. When the image sensor device 100 performs both the IPF operation and the IPL operation, the row driver 120 may further include an in-pixel LDB (IPL) latch circuit 127 in addition to the read latch circuit 121, the shutter latch circuit 122, the in-pixel FLT (IPF) latch circuit 123, the transfer logic circuit 124, the reset logic circuit 125, and the selection logic circuit 126.

An operation and a function of each component of the row driver 120 is similar to those described with reference to FIG. 7A. Accordingly, a difference that is provided as the row driver 120 further includes the IPL latch circuit 127 will be described in detail.

The IPL latch circuit 127 may receive an IPL vertical decoding signal VDEC_IPL from the address shifter 181. The IPL latch circuit 127 may receive an IPL latch set signal VDA_IPL_SET activating an operation in which the IPL latch circuit 127 stores and maintains an address, the latch control signal VDA_SET, and the latch reset signal VDA_RST from the timing controller 180.

The address shifter 181 included in the timing controller 180 may generate the IPL vertical decoding signal VDEC_IPL indicating a row address shifted from a row address corresponding to the vertical decoding signal VDEC as much as the given number of rows and may output the IPL vertical decoding signal VDEC_IPL to the IPL latch circuit 127.

For example, the IPL vertical decoding signal VDEC_IPL may indicate a row address that the IPL latch circuit 127 will store (i.e., an address of a row at which the IPL operation is to be performed). For example, the address of the row at which the IPL operation is to be performed may be an address shifted from the address of the row at which the readout operation is to be performed, as much as the given number of rows. For example, a row of the pixel array 110, at which the IPL operation is to be performed, may be one of rows of the pixel array 110, at which the readout operation is already completed.

For example, a pixel located at the row of the pixel array 110 at which the IPL operation is performed may be a pixel connected to a column line to which there is connected the pixel located at the row of the pixel array 110 at which the read operation is to be performed.

The IPL latch circuit 127 may store and maintain an address (hereinafter referred to as an “IPL address IPLA”) of a row of the pixel array 110, at which the IPL operation is to be performed, during the given time. The IPL latch circuit 127 may store and maintain the IPL address IPLA indicated by the IPL vertical decoding signal VDEC_IPL in response to the activated IPL latch set signal VDA_IPL_SET and the activated latch control signal VDA_SET. The IPL latch circuit 127 may provide the IPL address IPLA to the reset logic circuit 125 and the selection logic circuit 126.

The reset logic circuit 125 may provide the reset signal VRST to a pixel located at a row at which the readout operation, the shutter operation, or the IPF operation, or the IPL operation is to be performed, based on the readout address RDA, the shutter address SHA, the IPL address IPLA, or the IPF address IPFA.

The selection logic circuit 126 may provide the selection signal VSEL to the pixel located at the row at which the readout operation, the shutter operation, the IPF operation, or the IPL operation is to be performed, based on the readout address RDA, the IPF address IPFA, and the IPL address IPLA.

In some example embodiments, the selection logic circuit 126 of FIG. 10 may include the IPF control signal generation circuit 126a and the selection signal generation circuit 126b described with reference to FIG. 7B. Also, the selection logic circuit 126 may include an IPL control signal generation circuit to generate a control signal for the IPL operation. A configuration of the IPL control signal generation circuit may be identical to the configuration of the IPF control signal generation circuit 126a except for some signals input thereto.

In detail, like the IPF control signal generation circuit 126a, the IPL control signal generation circuit may include two inverters and three NAND gates. Also, the IPL control signal generation circuit may receive an IPL enable signal, an IPL address, etc. from the outside and may generate, for example, an IPL control signal in the same scheme as the IPF control signal generation circuit 126a. Also, the IPL control signal generation circuit may output the IPL control signal to the second NAND gate 126b_2 of the selection signal generation circuit 126b.

The selection signal generation circuit 126b may generate the selection signal VSEL based on the IPF control signal IPF_ctrl, the IPL control signal, and the readout control signal RD_O. The selection signal VSEL may be input to a pixel where the readout operation, the IPF operation, or the IPL operation is to be performed.

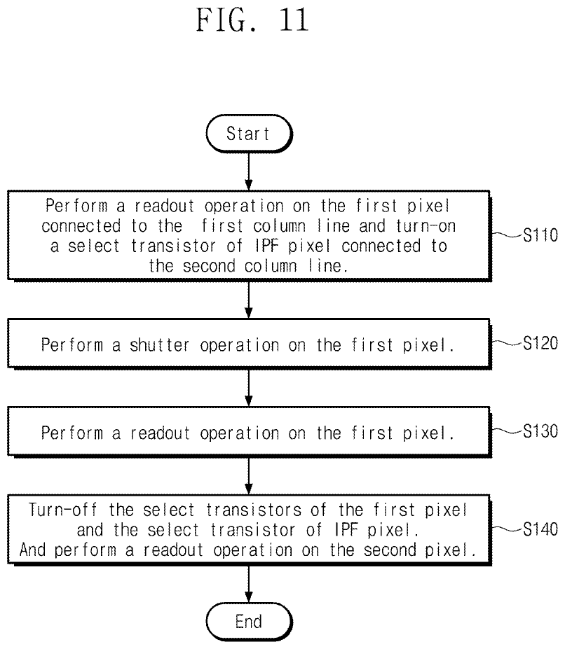

FIG. 11 is a flowchart illustrating an example of an operation method of an image sensor device for a pixel output control according to a column line change, according to some example embodiments of the present inventive concepts. The operation method shown in FIG. 11 may be performed by an image sensor device according to any of the example embodiments, including for example the image sensor device 100 shown in FIG. 1. Below, FIG. 11 will be described with reference to FIGS. 1, 6A, and 6B together.

In operation S110, the image sensor device 100 may turn on select transistors of pixels (e.g., PX1, also referred to herein as first pixels) where the readout operation is to be performed and may perform the readout operation. Also, the image sensor device 100 may turn on select transistors of pixels (e.g., PX_IPF, also referred to herein as second pixels) where the IPF operation is to be performed and may start the IPF operation. As the select transistors of the pixels (e.g., PX_IPF) where the IPF operation is to be performed are turned on, voltage levels of column lines (e.g., CL2) not connected to the pixels (e.g., PX1) where the readout operation is performed may start to be adjusted to a given voltage level based on pixel signals output by the “second pixels” (e.g., PX_IPF) to the column lines (e.g., CL2) during a particular time period (e.g., second time period). For example, the given voltage level may be determined based on the voltage level of the floating diffusion node FD which has been reset of the pixel (e.g., PX_IPF) where the IPF operation is performed.

The pixel (e.g., PX_IPF) where the IPF operation is performed may be a pixel not connected to the column line (e.g., CL1) connected to the pixel (e.g., PX1) where the readout operation is performed. Also, the pixel (e.g., PX_IPF) where the IPF operation is performed may be located at a row spaced from the pixel (e.g., PX1) where the readout operation is performed, as much as the given number of rows.

In operation S120, the image sensor device 100 may perform the shutter operation on the pixels (e.g., PX1) where the readout operation is performed. While the shutter operation is performed, the image sensor device 100 may turn off the select transistors of the pixels (e.g., PX1) where the shutter operation is performed. While the select transistors of the pixels where the shutter operation is performed are turned off, the image sensor device 100 may allow the select transistors of the pixels (e.g., PX_IPF) where the IPF operation is performed to maintain the turn-on state. As such, the IPF operation may be continuously performed on the column lines not connected to the pixels (e.g., PX1) where the shutter operation is performed.

In operation S130, the image sensor device 100 may turn on the select transistors of the pixels (e.g., PX1) where the shutter operation is performed and may perform the readout operation (e.g., such that a “first pixel” outputs first pixel signals to the column line CL1 during a first time period). While the readout operation is performed, the image sensor device 100 may allow the select transistors of the pixels (e.g., PX_IPF) where the IPF operation is performed to maintain the turn-on state. As such, the IPF operation may be continuously performed on the column lines not connected to the pixels (e.g., PX1) where the readout operation is performed (e.g., the second time period during which the voltage of the column line CL2 is adjusted by the IPF operation of the “second pixel PX_IPF” overlaps the first time period during which the “first pixel” PX1 outputting the first pixel signal through the column line CL1.

In operation S140, the image sensor device 100 may turn off the select transistors of the pixels (e.g., PX1) where the readout operation is performed and may end the readout operation. Also, the image sensor device 100 may turn off the select transistors of the pixels (e.g., PX_IPF) where the IPF operation is performed and may end the IPF operation. Meanwhile, the image sensor device 100 may turn on select transistors of pixels (e.g., PX2) connected to column lines (e.g., CL2) where the pixels (e.g., PX_IPF) performing the IPF operation are connected thereto. As such, in operation S110 to operation S130, the image sensor device 100 may perform the readout operation on the pixels (e.g., PX2) connected to the column lines (e.g., CL2) where to which the pixels (e.g., PX_IPF) performing the IPF operation are connected.

According to some example embodiments of the present inventive concepts, it may be possible to prevent a voltage settling time when a location of a column line connected to a pixel where a readout operation is performed is switched.

Accordingly, according to some example embodiments of the present inventive concepts, the accuracy of correlated double sampling (CDS) for each column line may be improved, and the decrease in a dynamic range of an image sensor may be reduced, minimized, or prevented. Also, a speed at which a pixel signal is output may be improved, and thus performance of the image sensor device 100 may be improved.

As described herein, any devices, systems, units, circuits, controllers, processors, and/or portions thereof according to any of the example embodiments (including, for example, the image sensor device 100, the pixel array 110, the row driver 120, the active load circuit 130, the line disconnection circuit 140, the multiplexer unit 150, the ramp generator 160, the analog-digital converter 170, the timing controller 180, the address shifter 181, the output circuit 190, the read latch circuit 121, the shutter latch circuit 122, the IPF latch circuit 123, the transfer logic circuit 124, the reset logic circuit 125, the selection logic circuit 126, the IPL latch circuit 127, any portion thereof, or the like) may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, units, circuits, controllers, processors, and/or portions thereof according to any of the example embodiments.

While the present inventive concepts have been described with reference to some example embodiments thereof, it will be apparent to those of ordinary skill in the art that various changes and modifications may be made thereto without departing from the spirit and scope of the present inventive concepts as set forth in the following claims.

What is claimed is:

1. An image sensor device, comprising:
a first pixel located at a first row and a first column and comprising a first select transistor, the first pixel configured to output a first pixel signal through a first column line; and
a second pixel located at a second row and the first column and comprising a second select transistor, the second row different from the first row, the second pixel configured to output a second pixel signal through a second column line before the first pixel signal is output,
wherein, during a first time period, the first select transistor is turned on and the first pixel signal is output, and
wherein, during a second time period, the second select transistor is turned on, and a first voltage is applied to the second column line through the second select transistor, the second time period including the first time period.

2. The image sensor device of claim 1, wherein the first voltage is based on a voltage level of a floating diffusion node which has been reset of the second pixel.

3. The image sensor device of claim 2, wherein
the second pixel further includes a reset transistor connected to the floating diffusion node of the second pixel,
the voltage level of the floating diffusion node which has been reset of the second pixel is based on a voltage level of a reset signal of a logic high level that is input to the reset transistor, and
a voltage level of the reset signal of the logic high level that is input before the second time period is different from a voltage level of the reset signal of the logic high level that is input after the second time period.

4. The image sensor device of claim 1, wherein
the second time period further includes a third time period and a fourth time period,
during the third time period, the first select transistor is turned off, and
during the fourth time period, the first select transistor is turned on.

5. The image sensor device of claim 1, further comprising:
a row driver configured to generate first control signal for controlling the first pixel and a second control signal for controlling the second pixel,
wherein the first control signal and the second control signal are provided to the first pixel and the second pixel; and
a timing controller configured to control the row driver,
wherein the row driver is configured to, based on the second control signal, turn on the second select transistor in the second time period such that the first voltage is applied to the second column line through the second select transistor, and
wherein an address of the second row is based on an address of the first row.

6. The image sensor device of claim 5, wherein the row driver includes:
a first latch circuit configured to receive the address of the first row from the timing controller;
a second latch circuit configured to receive the address of the second row from the timing controller; and
logic circuits configured to receive the addresses of the first and second rows from the first and second latch circuits and to transmit the first and second control signals to the first pixel and the second pixel of a pixel array.

7. The image sensor device of claim 6, wherein
the logic circuits include a selection logic circuit configured to output a first selection signal to the first select transistor in response to the address of the first row and to output a second selection signal to the second select transistor in response to the address of the second row,
the first select transistor is configured to be turned on or turned off in response to the first selection signal, and
the second select transistor is configured to be turned on or turned off in response to the second selection signal.

8. The image sensor device of claim 5, wherein the timing controller includes an address shifter configured to generate the address of the second row based on shifting the address of the first row.

9. The image sensor device of claim 5, further comprising:
a line disconnection circuit including a plurality of transistors connected to the first and second column lines and configured to adjust voltage levels of the first and second column lines to a second voltage,
wherein the plurality of transistors are configured to be turned off in response to the first select transistor being turned on, and
wherein the plurality of transistors are configured to be turned on in response to the first select transistor being turned off such that a voltage of the first column line is adjusted to the second voltage.

10. The image sensor device of claim 9, wherein
the timing controller further includes a register, and
the image sensor device is configured to, depending on a value stored in the register,
cause the first voltage to be applied to the second column line based on using the second select transistor, or
cause the voltage of the first column line to be adjusted to the second voltage based on using the line disconnection circuit.

11. The image sensor device of claim 9, further comprising:
a first semiconductor substrate; and
a second semiconductor substrate,
wherein the first semiconductor substrate and the second semiconductor substrate are electrically connected to each other,
wherein the first pixel and the second pixel are on the first semiconductor substrate, and
wherein the row driver, the timing controller, and the line disconnection circuit are on the second semiconductor substrate.

12. An image sensor device, comprising:
a first pixel located at a first row and a first column and comprising a first select transistor, the first pixel configured to output a first pixel signal through a first column line;
a second pixel located at a second row and the first column and comprising a second select transistor, the second row different from the first row, the second pixel configured to output a second pixel signal through a second column line before the first pixel signal is output; and
a third pixel located at a third row and the first column and comprising a third select transistor, the third row different from both the first row and the second row, the third pixel configured to output a third pixel signal through the first column line before the first pixel signal is output,
wherein, during a first time period and a second time period, the first select transistor is turned on and the first pixel signal is output,
wherein, during a third time period, the second select transistor is turned on, and a first voltage is applied to the second column line through the second select transistor, the second time period including the first time period and the second time period, and
wherein, during a fourth time period, the first select transistor is turned off, the third select transistor is turned on, and a second voltage is applied to the first column line through the third select transistor, the fourth time period between the first time period and the second time period.

13. The image sensor device of claim 12, wherein
the first voltage is based on a voltage level of a floating diffusion node which has been reset of the second pixel, and
the second voltage is based on a voltage level of a floating diffusion node which has been reset of the third pixel.

14. The image sensor device of claim 12, further comprising:
a row driver configured to generate first control signal for controlling the first pixel, a second control signal for controlling the second pixel and a third control signal for controlling the third pixel,
wherein the first to third control signals are provided to the first to third pixels, respectively; and
a timing controller configured to control the row driver,
wherein, based on the first to third control signals, the row driver is configured to:
turn on the first select transistor and turn off the third select transistor, during the first time period and the second time period;
turn off the first select transistor and turn on the third select transistor such that the second voltage is applied to the second column line through the third select transistor, during the fourth time period; and
turn on the second select transistor such that the first voltage is applied to the second column line through the second select transistor, during the third time period, and
wherein an address of the second row and an address of the third row are based on an address of the first row.

15. The image sensor device of claim 14, further comprising:
a line disconnection circuit including a plurality of transistors connected to the first and second column lines and configured to adjust voltage levels of the first and second column lines to a third voltage,
wherein the plurality of transistors are configured to be turned on in response to the first select transistor being turned off, and
wherein the plurality of transistors are configured to be turned off in response to the first select transistor being turned on such that a voltage of the first column line is adjusted to the third voltage.

16. The image sensor device of claim 15, wherein
the timing controller further includes a register, and
the image sensor device is configured to, based on a value stored in the register, perform at least one of
an operation of applying the second voltage to the first column line based on using the third select transistor,
an operation of adjusting the voltage of the first column line to the third voltage based on using the line disconnection circuit, or
an operation of applying the first voltage to the second column line based on using the second select transistor is performed.

17. The image sensor device of claim 15, further comprising:
a first semiconductor substrate; and
a second semiconductor substrate,
wherein the first semiconductor substrate and the second semiconductor substrate are electrically connected to each other,
wherein the first pixel, the second pixel, and the third pixel are on the first semiconductor substrate, and
wherein the row driver, the timing controller, and the line disconnection circuit are on the second semiconductor substrate.

18. An operation method of an image sensor device which includes a first pixel located at a first row and a first column and including a first select transistor, a second pixel located at a second row and the first column and including a second select transistor, the second row different from the first row, a first column line connected to the first pixel, and a second column line connected to the second pixel, the operation method comprising:
performing a first readout operation based on turning on the first select transistor and starting an operation of applying a first voltage to the second column line based on turning on the second select transistor;
terminating the first readout operation based on turning off the first select transistor and performing a shutter operation;
terminating the shutter operation based on turning on the first select transistor and performing a second readout operation; and
terminating the second readout operation based on turning off the first select transistor and terminating an operation of applying the first voltage to the second column line based on turning off the second select transistor,
wherein an address of the second row is based on an address of the first row.

19. The operation method of claim 18, wherein the first voltage is based on a voltage level of a floating diffusion node which has been reset of the second pixel.

20. The operation method of claim 18, further comprising:
determining the address of the second row by shifting the address of the first row.
